(19) United States
(12) Patent Application Publication
(10) Pub. No.: US 2016/0313639 A1
(43) Pub. Date: Oct. 27, 2016

(54) PHOTOSENSITIVE RESIN COMPOSITION, PIXEL LAYER, PROTECTIVE FILM, SPACER, THIN-FILM TRANSISTOR, COLOR FILTER, AND LIQUID CRYSTAL DISPLAY APPARATUS

(71) Applicant: Chi Mei Corporation, Tainan City (TW)

(72) Inventors: Cheng-Chang Hsu, Taichung City (TW); Bar-Yuan Hsieh, Taichung City (TW)

(21) Appl. No.: 15/099,615

(22) Filed: Apr. 15, 2016

(30) Foreign Application Priority Data
Apr. 22, 2015 (TW) 104112843

(51) Int. Cl. G03F 7/00; G02B 1/14; G02F 1/1339; G02F 1/1368; G02F 1/1335; G03F 7/038; G02B 5/22

(52) U.S. Cl. CPC G03F 7/0007; G03F 7/038; G02B 1/14; G02B 5/223; G02F 1/1368; G02F 1/133514; G02F 1/1339; G02F 2001/13398

(57) ABSTRACT

The invention provides a photosensitive resin composition that can be applied in a pixel layer, a protective film, a spacer, a thin-film transistor, a color filter, and a liquid crystal display apparatus and can provide good development properties and high-precision pattern linearity. The photosensitive resin composition includes: an alkali-soluble resin (A), a compound (B) containing an ethylenically unsaturated group, a photoinitiator (C), an organic solvent (D), and a compound (E) represented by formula (1).

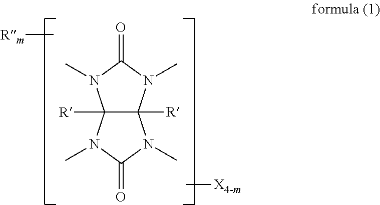

### CROSS-REFERENCE TO RELATED APPLICATION

This application claims the priority benefit of Taiwan application serial no. 104112843, filed on Apr. 22, 2015. The entirety of the above-mentioned patent application is hereby incorporated by reference herein and made a part of this specification.

### BACKGROUND OF THE INVENTION

1. Field of the Invention

The invention relates to a photosensitive resin composition and an application thereof, and more particularly, to a photosensitive resin composition capable of providing good development properties and high-precision pattern linearity and an application thereof.

2. Description of Related Art

Due to characteristics such as lightweight, slim design, and low power consumption, the liquid crystal display apparatus can be applied in various applications such as personal computers, personal digital assistants, digital cameras, and desktop computer monitors. However, such liquid crystal display apparatus needs to have a color filter having a high color reproduction range.

The color filter is obtained by forming different hues of three colors, red (R), green (G), and blue (B) into stripe or mosaic shapes on a surface of a support such as a glass or a plastic sheet on which a black matrix (BM) is formed.

Up to now, various manufacturing methods of a color filter have been proposed, wherein a negative photosensitive coloring composition is most commonly used for the manufacture of a color filter. The negative photosensitive coloring composition includes, for instance, a pigment, an acrylic resin, as photopolymerization initiator, and a reactive polymer. The curing of the negative photosensitive coloring composition includes, for instance, the following method: producing a free radical by decomposing or activating a photopolymerization initiator via UV irradiation. Then, the free radical activates an ethylenically unsaturated compound such that the ethylenically unsaturated compound is reacted in a free radical polymerization reaction. When using the negative photosensitive coloring composition to form a color filter, the negative photosensitive coloring composition is generally coated on a substrate, and then development is performed after UV irradiation is performed via a photomask to obtain a pattern. Baking is performed on the pattern formed by the method such that the pattern is fixedly stuck on the substrate. A pixel pattern is thus formed. The cycle is repeated with the required colors to obtain a pattern of colored coating. However, if the cycle is repeated, a larger segment deviation is generated in the end of the BM and RGB pixels. Uneven color display is generated due to the segment deviation. In order to inhibit the segment deviation, a transparent resin layer (protective film) is used for the planarization treatment of the color filter.

The protective film needs to have features such as the ability to protect the RGB colored layer, heat resistance when liquid crystals are being filled, and hardness against pressure. To achieve the expected hardness, a photosensitive curable resin composition with high cross linking density is developed (Japanese Laid-Open Patent Publication No. 5-78483). However, the photosensitive curable resin composition is contracted during curing, thereby generating residual stress. As a result, a defect of poor high-precision pattern linearity readily occurs.

Therefore, how to improve the development properties and the high-precision pattern linearity at the same time to meet the requirements of the current industry is a research goal in the technical field of the invention.

### SUMMARY OF THE INVENTION

Based on the above, the invention provides a photosensitive resin composition that can be applied in a protective film, a spacer, a pixel layer, a color filter, a thin-film transistor, and a liquid crystal display apparatus and can provide good development properties and high-precision pattern linearity.

The invention provides a photosensitive resin composition including: an alkali-soluble resin (A), a compound (B) containing an ethylenically unsaturated group, a photoinitiator (C), an organic solvent (D), and a compound (E) represented by formula (1).

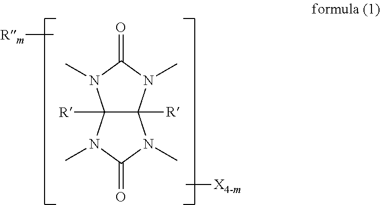

In formula (1), R′ each independently represent a hydrogen atom, a C₁ to C₂₀ substituted or unsubstituted hydrocarbon group or acyl group, R″ each independently represent a hydrogen atom, a C₁ to C₁₅ substituted or unsubstituted hydrocarbon group, acyl group, or nitro group, m represents an integer of 0, 1, or 2, and X is a group having a structure represented by formula (2):

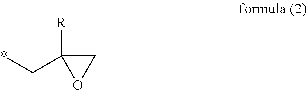

In formula (2), R represents a hydrogen atom or a C₁ to C₄ alkyl group.

In an embodiment of the invention, the alkali-soluble resin (A) includes a first alkali-soluble resin (A-1) having an unsaturated group, wherein the first alkali-soluble resin (A-1) having an unsaturated group is obtained by performing a polymerization reaction on a mixture of an epoxy compound (a1) having at least two epoxy groups and a compound (a2) having at least one carboxylic acid group and at least one ethylenically unsaturated group.

In an embodiment of the invention, the epoxy compound (a1) having at least two epoxy groups is selected from the group consisting of a compound represented by formula (3) and a compound represented by formula (4),

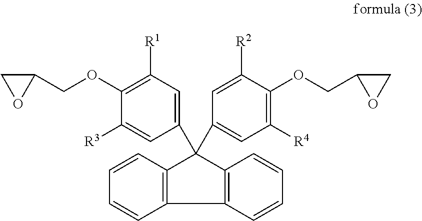

In formula (3), R¹, R², R³, and R⁴ each independently represent a hydrogen atom, a halogen, or a C₁ to C₅ alkyl group;

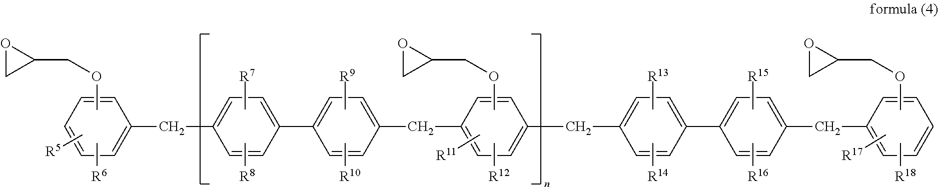

In formula (4), R⁵ to R¹⁸ each independently represent a hydrogen atom, a halogen, a C₁ to C₈ alkyl group, or a C₆ to C₁₅ aryl group, and n represents an integer of 0 to 10.

In an embodiment of the invention, based on a total usage amount of 100 parts by weight of the alkali-soluble resin (A), the total usage amount of the first alkali-soluble resin (A-1) having an unsaturated group is 0 parts by weight to 80 parts by weight.

In an embodiment of the invention, the compound (B) containing an ethylenically unsaturated group includes at least one compound (B-1) selected from the group consisting of a compound represented by formula (5) and a compound represented by formula (6),

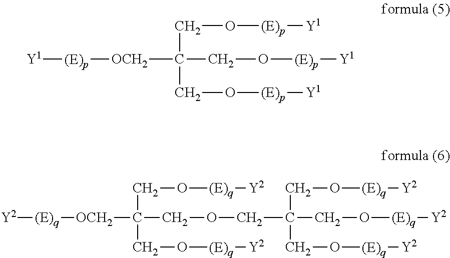

In formula (5) and formula (6), E each independently represent —((CH2)_{z}CH₂O)— or —((CH₂)_{z}CH(CH₃)O)—, z each independently represent an integer of 1 to 10, Y¹ and Y² each independently represent an acryl group, a methacryl group, a hydrogen atom, or a carboxylic group; in formula (5), the sum of the acryl group and the methacryl group represented by Y¹ is 3 or 4, p each independently represent an integer of 0 to 10, the sum of each p is an integer of 1 to 40; in formula (6), the sum of the acryl group and the methacryl group represented by Y² is 5 or 6, q each independently represent an integer of 0 to 10, and the sum of each q is an integer of 1 to 60.

In an embodiment of the invention, based on a total usage amount of 100 parts by weight of the alkali-soluble resin (A), the usage amount of the at least one compound (B-1) selected from the group consisting of the compound represented by formula (5) and the compound represented by formula (6) is between 10 parts by weight and 100 parts by weight.

In an embodiment of the invention, based on a total usage amount of 100 parts by weight of the alkai-soluble resin (A), the usage amount of the compound (B) containing an ethylenically unsaturated group is 60 parts by weight to 600 parts by weight; the usage amount of the photoinitiator (C) is 20 parts by weight to 200 parts by weight; the usage amount of the organic solvent (D) is 500 parts by weight to 5000 parts by weight; and the usage amount of the compound (E) represented by formula (1) is 3 parts by weight to 30 parts by weight.

In an embodiment of the invention, a pigment (F) is further included.

In an embodiment of the invention, based on a total usage amount of 100 parts by weight of the alkali-soluble resin (A), the usage amount of the pigment (F) is 40 parts by weight to 400 parts by weight.

In an embodiment of the invention, a dye (G) is further included.

In an embodiment of the invention, based on a total usage amount of 100 parts by weight of the alkali-soluble resin (A), the usage amount of the dye (G) is 3 parts by weight to 30 parts by weight.

The invention provides a protective film formed by the above photosensitive resin composition.

The invention provides a spacer formed by the above photosensitive resin composition.

The invention provides a pixel layer formed by the above photosensitive resin composition.

The invention provides a thin-film transistor containing the above protective film.

The invention provides a color filter containing the above protective film.

The invention provides a color filter containing the above spacer.

The invention provides a color filter containing the above pixel layer.

The invention provides a liquid crystal display apparatus containing the above thin-film transistor.

The invention further provides a liquid crystal display apparatus containing the above color filter.

Based on the above, the photosensitive resin composition of the invention contains a specific compound (E), and therefore can provide good development properties and high-precision pattern linearity, and is suitable for a protective film, a spacer, a pixel layer, a color filter, a thin-film transistor, and a liquid crystal display apparatus.

In order to make the aforementioned features and advantages of the disclosure more comprehensible, embodiments accompanied with figures are described in detail below.

### DESCRIPTION OF THE EMBODIMENTS

### <Photosensitive Resin Composition>

The invention provides a photosensitive resin composition including: an alkali-soluble resin (A), a compound (B) containing an ethylenically unsaturated group, a photoinitiator (C), an organic solvent (D), and a compound (E). Moreover, if needed, the photosensitive resin composition can further include at least one of a pigment (F), a dye (G), and an additive (H). In the following, the individual components used in the photosensitive resin composition of the invention are described in detail.

It should be mentioned that, in the following, (meth)acrylic acid represents acrylic acid and/or methacrylic acid, and (meth)acrylate represents acrylate and/or methacrylate. Similarly, (meth)acryloyl group represents acryloyl group and/or methacryloyl group.

### Alkali-Soluble Resin (A)

The alkali-soluble resin (A) includes a first alkali-soluble resin (A-1) having an unsaturated group. Moreover, the alkali-soluble resin (A) can further include a second alkali-soluble resin (A-2).

### First Alkali-Soluble Resin (A-1) Having an Unsaturated Group

The first alkali-soluble resin (A-1) having an unsaturated group is obtained by performing a polymerization reaction on a mixture of an epoxy compound (a1) having at least two epoxy groups and a compound (a2) having at least one carboxylic acid group and at least one ethylenically unsaturated group. Moreover, in the polymerization reaction of the first alkali-soluble resin (A-1), a carboxylic anhydride compound (a3), a compound (a4) containing an epoxy group, or a combination of the two can further be optionally included.

### Epoxy Compound (a1) Having at Least Two Epoxy Groups

The epoxy compound (a1) having at least two epoxy groups is selected from the group consisting of a compound represented by formula (3) and a compound represented by formula (4).

Specifically, the compound represented by formula (3) is as follows.

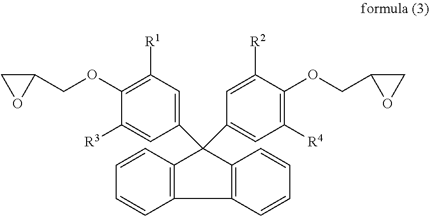

In formula (3), R¹, R², R³, and R⁴ each independently represent a hydrogen atom, halogen, or a C₁ to C₅ alkyl group.

The compound represented by formula (3) can be obtained by reacting a bisphenol fluorene compound with an epihalohydrin.

In particular, specific examples of the bisphenol fluorene compound include: 9,9-bis(4-hydroxyphenyl)fluorene, 9,9-bis(4-hydroxy-3-methylphenyl)fluorene, 9,9-bis(4-hydroxy-3-chlorophenyl)fluorene, 9,9-bis(4-hydroxy-3-bromophenyl)fluorene, 9,9-bis (4-hydroxy-3-fluorophenyl)fluorene, 9,9-bis(4-hydroxy-3-methoxyphenyl)fluorene, 9,9-bis(4-hydroxy-3,5-dimethylphenyl)fluorene, 9,9-bis(4-hydroxy-3,5-dichlorophenyl)fluorene, 9,9-bis(4-hydroxy-3,5-dibromophenyl)fluorene, a similar compound thereof, or a combination of the compounds.

Specific examples of the epihalohydrin include epichlorohydrin, epibromohydrin, or a combination of the compounds.

Specific examples of the bisphenol fluorene-type compound having an epoxy group include (1) products made by Nippon Steel Chemical Co., Ltd. such as ESF-300 or a similar compound thereof; (2) products made by Osaka Gas Co., Ltd. such as PG-100, EG-210, or a similar compound thereof; and (3) products made by S.M.S. Technology Co., Ltd. such as SMS-F9PhPG, SMS-F9CrG, SMS-F914PG, or a similar compound thereof.

More specifically, the compound represented by formula (4) is as follows.

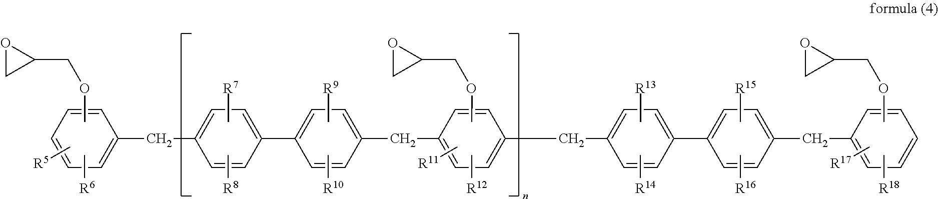

In formula (4), R⁵ to R¹⁸ each independently represent a hydrogen atom, a halogen, a C₁ to C₈ alkyl group, or a C₆ to C₁₅ aryl group, and n represents an integer of 0 to 10.

The compound represented by formula (4) can be obtained by reacting a compound represented by formula (4-1) and the epihalohydrin in the presence of an alkali metal hydroxide.

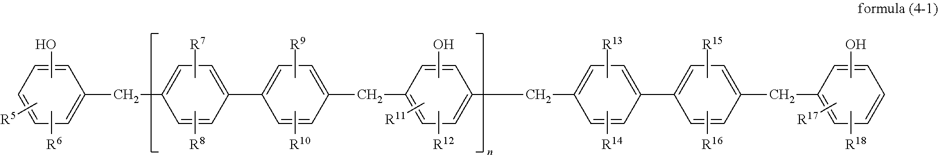

In formula (4-1), the definition of each of R⁵ to R¹⁸ and n is the same as the definition of each of R⁵ to R¹⁸ and n in formula (4), and is not repeated herein.

The method for synthesizing the compound represented by formula (4-1) is as follows: first, a condensation reaction is performed on a compound represented by formula (4-2) and a phenol in the presence of an acid catalyst to form the compound represented by formula (4-1). Then, an excess amount of the epihalohydrin is added to perform a dehydrohalogenation reaction on the epihalohydrin and the compound represented by formula (4-1) to obtain the compound represented by formula (4).

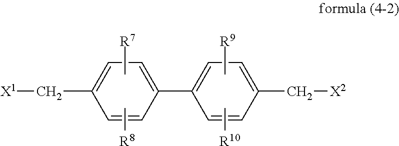

In formula (4-2), the definition of each of R⁷ to R¹⁰ is the same as the definition of each of R⁷ to R¹⁰ in formula (4), and is not repeated herein. X¹ and X² each independently represent a halogen atom, a C₁ to C₆ alkyl group, or a C₁ to C₆ alkoxy group. The halogen atom can be chlorine or bromine. The alkyl group is preferably a methyl group, an ethyl group, or a t-butyl group. The alkoxy group is preferably a methoxy group or an ethoxy group.

Specific examples of phenol include: phenol, cresol, ethylphenol, n-propylphenol, isobutylphenol, t-butylphenol, octylphenol, nonylphenol, xylenol, methylbutylphenol, di-t-butylphenol, vinylphenol, propenylphenol, ethinylphenol, cyclopentylphenol, cyclohexylphenol, cyclohexylcresol, or a similar compound thereof. The phenol can be used alone or in multiple combinations.

Based on a usage amount of 1 mole of the compound represented by formula (4-2), the usage amount of the phenol is 0.5 moles to 20 moles, preferably 2 moles to 15 moles.

Specific examples of the acid catalyst include: hydrochloric acid, sulfuric acid, p-toluenesulfonic acid, oxalic acid, boron trifluoride, aluminium chloride anhydrous, zinc chloride, or a similar compound thereof. The acid catalyst is preferably p-toluenesulfonic acid, sulfuric acid, hydrochloric acid, or a combination of the compounds. The acid catalyst can be used alone or in multiple combinations.

Moreover, although the usage amount of the acid catalyst is not particularly limited, based on a usage amount of 100 wt % of the compound represented by formula (4-2), the usage amount of the acid catalyst is preferably 0.1 wt % to 30 wt %.

The condensation reaction can be performed without a solvent or in the presence of an organic solvent. Moreover, specific examples of the organic solvent include: toluene, xylene, methyl isobutyl ketone, or a similar compound thereof. The organic solvent can be used alone or in multiple combinations.

Based on a total weight of 100 wt % of the compound represented by formula (4-2) and the phenol, the usage amount of the organic solvent is 50 wt % to 300 wt %, preferably 100 wt % to 250 wt %. Moreover, the operating temperature of the condensation reaction is 40° C. to 180° C. and the operating time of the condensation reaction is 1 hour to 8 hours.

After the condensation reaction is complete, a neutralization treatment or a rinse treatment can be performed. In the neutralization treatment, the pH value of the reacted solution is adjusted to pH 3 to pH 7, preferably pH 5 to pH 7. The rinse treatment can be performed by using a neutralizer, wherein the neutralizer is an alkaline substance, and specific examples thereof include: an alkali metal hydroxide such as sodium hydroxide, potassium hydroxide, or a similar compound thereof; an alkaline earth metal hydroxide such as calcium hydroxide, magnesium hydroxide, or a similar compound thereof; an organic amine such as diethylene triamine, triethylenetetramine, aniline, phenylene diamine, or a similar compound thereof; and ammonia, sodium dihydrogen phosphate, or a combination of the compounds. The neutralizer can be used alone or in multiple combinations. The rinse treatment can be performed with a known method, such as adding an aqueous solution containing a neutralizer in the reacted solution and then extracting repeatedly. After the neutralization treatment or the rinse treatment, the unreacted phenol and solvent can be distilled off by a heat treatment under reduced pressure, and then condensation is performed to obtain the compound represented by formula (4-1).

Specific examples of the epihalohydrin include: epichlorohydrin, epibromohydrin, or a combination of the compounds. Before the dehydrohalogenation reaction is performed, an alkali metal hydroxide such as sodium hydroxide or potassium hydroxide can be pre-added or added during the reaction process. The operating temperature of the dehydrohalogenation reaction is 20° C. to 120° C. and the operating time thereof ranges from 1 hour to 10 hours.

In an embodiment, the alkali metal hydroxide added in the dehydrohalogenation reaction can also be an aqueous solution thereof. In the present embodiment, when an aqueous solution of the alkali metal hydroxide is continuously added to the dehydrohalogenation reaction system, water and the epihalohydrin can be continuously distilled under reduced pressure or atmospheric pressure at the same time to separate and remove water, and the epihalohydrin can be continuously flown back into the reaction system.

Before the dehydrohalogenation reaction is performed, a quaternary ammonium salt such as tetramethyl ammonium chloride, tetramethyl ammonium bromide, trimethyl benzyl ammonium chloride, or a similar compound thereof can also be added as a catalyst, and then an alkali metal hydroxide or an aqueous solution thereof is added after the mixture is reacted at 50° C. to 150° C. for 1 hour to 5 hours. Then, the mixture is reacted for 1 hour to 10 hours at a temperature of 20° C. to 120° C. to perform a dehydrohalogenation reaction.

Based on a total equivalent of 1 equivalent of the hydroxyl group in the compound represented by formula (4-1), the usage amount of the epihalohydrin is 1 equivalent to 20 equivalents, preferably 2 equivalents to 10 equivalents. Based on a total equivalent of 1 equivalent of the hydroxyl group in the compound represented by formula (4-1), the usage amount of the alkali metal hydroxide added in the dehydrohalogenation reaction is 0.8 equivalents to 15 equivalents, preferably 0.9 equivalents to 11 equivalents.

Moreover, to facilitate the dehydrohalogenation reaction, an alcohol such as methanol, ethanol, or a similar compound thereof can also be added. In addition, an aprotic polar solvent such as dimethyl sulfone, dimethyl sulfoxide, or a similar compound thereof can also be added to perform the reaction. When an alcohol is used, based on a total amount of 100 wt % of the epihalohydrin, the usage amount of the alcohol is 2 wt % to 20 wt %, preferably 4 wt % to 15 wt %. When an aprotic polar solvent is used, based on a total amount of 100 wt % of the epihalohydrin, the usage amount of the aprotic polar solvent is 5 wt % to 100 wt %, preferably 10 wt % to 90 wt %.

After the dehydrohalogenation reaction is complete, a rinse treatment can be optionally performed. Then, the epihalohydrin, the alcohol, and the aprotic polar solvent are removed by using a method of distillation under reduced pressure at, for instance, a temperature of 110° C. to 250° C. and a pressure of equal to or less than 1.3 kPa (10 mmHg).

To prevent the epoxy resin formed from containing a hydrolyzable halogen, the solution after the dehydrohalogenation reaction can be added in a solvent such as toluene or methyl isobutyl ketone and an aqueous solution of alkali metal hydroxide such as sodium hydroxide or potassium hydroxide, and then the dehydrohalogenation reaction is performed again. In the dehydrohalogenation reaction, based on a total equivalent of 1 equivalent of the hydroxyl group in the compound represented by formula (4-1), the usage amount of the alkali metal hydroxide is 0.01 moles to 0.3 moles, preferably 0.05 moles to 0.2 moles. Moreover, the operating temperature of the dehydrohalogenation reaction ranges from 50° C. to 120° C. and the operating time thereof ranges from 0.5 hours to 2 hours.

After the dehydrohalogenation reaction is complete, the salts are removed through steps such as filtering and rinsing. Moreover, a method of distillation under reduced pressure is used to remove solvents such as toluene and methyl isobutyl ketone to obtain the compound represented by formula (4). Specific examples of the compound represented by formula (4) include products such as NC-3000, NC-3000H, NC-3000S, and NC-3000P manufactured by Nippon Kayaku Co., Ltd.

### Compound (a2) Having at Least One Carboxylic Acid Group and at Least One Ethylenically Unsaturated Group

Specific examples of the compound (a2) having at least one carboxylic acid group and at least one ethylenically unsaturated group are selected from the group consisting of the following (1) to (3): (1) acrylic acid, methacrylic acid, 2-methacryloyloxyethylbutanedioic acid, 2-methacryloyloxybutylbutanedioic acid, 2-methacryloyloxyethylhexanedioic acid, 2-methacryloyloxybutylhexanedioic acid, 2-methacryloyloxyethylhexahydrophthalic acid, 2-methacryloyloxyethylmaleic acid, 2-methacryloyloxypropylmaleic acid, 2-methacryloyloxybutylmaleic acid, 2-methacryloyloxypropylbutanedioic acid, 2-methacryloyloxypropylhexanedioic acid, 2-methacryloyloxypropyltetrahydrophthalic acid, 2-methacryloyloxypropylphthalic acid, 2-methacryloyloxybutylphthalic acid, or 2-methacryloyloxybutylhydrophthalic acid; (2) a compound obtained by reacting (meth)acrylate containing a hydroxyl group with a dicarboxylic acid compound, wherein the dicarboxylic acid compound includes adipic acid, succinic acid, maleic acid, or phthalic acid; and (3) a hemiester compound obtained by reacting (meth)acrylate containing a hydroxyl group with the carboxylic anhydride compound (a3) above, wherein the (meth)acrylate containing a hydroxyl group includes (2-hydroxyethyl) acrylate, (2-hydroxyethyl) methacrylate, (2-hydroxypropyl) acrylate, (2-hydroxypropyl) methacrylate, (4-hydroxybutyl) acrylate, (4-hydroxybutyl) methacrylate, or pentaerythritol trimethacrylate. Moreover, the carboxylic anhydride compound here can be the same as the carboxylic anhydride compound (a3) contained in the polymerization reaction of the first alkali-soluble resin (A-1) above, and is not repeated herein.

### Carboxylic Anhydride Compound (a3)

The carboxylic anhydride compound (a3) can be selected from the group consisting of the following (1) to (2): (1) a dicarboxylic anhydride compound such as butanedioic anhydride, maleic anhydride, itaconic anhydride, phthalic anhydride, tetrahydrophthalic anhydride, hexahydrophthalic anhydride, methyl tetrahydrophthalic anhydride, methyl hexahydrophthalic anhydride, methyl endo-methylene tetrahydro phthalic anhydride, chlorendic anhydride, glutaric anhydride, or 1,2,4-benzene tricarboxylic anhydride; and (2) a tetracarboxylic anhydride compound such as benzophenone tetracarboxylic dianhydride (BTDA), biphenyl tetracarboxylic dianhydride, or biphenyl ether tetracarboxylic dianhydride.

### Compound (a4) Containing an Epoxy Group

The compound (a4) containing an epoxy group can be selected from glycidyl methacrylate, 3,4-epoxycyclohexylmethacrylate, a glycidyl ether compound containing an unsaturated group, an unsaturated compound containing an epoxy group, or a combination of the compounds. The glycidyl ether compound containing an unsaturated group includes products made by Nagase Kasei Kogyo Co., Ltd. such as Denacol EX-111, Denacol EX-121, Denacol EX-141, Denacol EX-145, Denacol EX-146, Denacol EX-171, or Denacol EX-192.

The first alkali-soluble resin (A-1) can be a reaction product containing a hydroxyl group formed by performing a polymerization reaction on the epoxy compound (a1) having at least two epoxy groups and the compound (a2) having at least one carboxylic acid group and at least one ethylenically unsaturated group. In particular, the epoxy compound (a1) having at least two epoxy groups is a compound represented by formula (3). Then, the carboxylic anhydride compound (a3) is added to the reaction solution to perform a polymerization reaction. Based on a total equivalent of 1 equivalent of the hydroxyl group of the reaction product containing a hydroxyl group, the equivalent of the acid anhydride group contained in the carboxylic anhydride compound (a3) is preferably 0.4 equivalents to 1 equivalent, more preferably 0.75 equivalents to 1 equivalent. When a plurality of the carboxylic anhydride compounds (a3) is used, the carboxylic anhydride compounds can be added to the reaction in sequence or at the same time. When a dicarboxylic anhydride compound and a tetracarboxylic anhydride compound are used as the carboxylic anhydride compound (a3), the molar ratio of the dicarboxylic anhydride compound and the tetracarboxylic anhydride compound is preferably 1/99 to 90/10, more preferably 5/95 to 80/20. Moreover, the operating temperature of the reaction can be 50° C. to 130° C.

The first alkali-soluble resin (A-1) can be a reaction product containing a hydroxyl group formed by performing a reaction on the epoxy compound (a1) having at least two epoxy groups and the compound (a2) having at least one carboxylic acid group and at least one ethylenically unsaturated group. In particular, the epoxy compound (a1) having at least two epoxy groups is a compound represented by formula (4). Then, the carboxylic anhydride compound (a3), the compound (a4) containing an epoxy group, or a combination of the two is added to the reaction solution to perform a polymerization reaction. Based on a total equivalent of 1 equivalent of the epoxy groups in the compound represented by formula (4), the acid value equivalent of the compound (a2) having at least one carboxylic acid group and at least one ethylenically unsaturated group is preferably 0.8 equivalents to 1.5 equivalents, more preferably 0.9 equivalents to 1.1 equivalents. Based on a total usage amount of 100 mole % of the hydroxyl group of the reaction product containing a hydroxyl group, the usage amount of the carboxylic anhydride compound (a3) is 10 mole % to 100 mole %, preferably 20 mole % to 100 mole %, and more preferably 30 mole % to 100 mole %.

When preparing the first alkali-soluble resin (A-1), to reduce the reaction time, a basic compound is generally added to the reaction solution as a reaction catalyst.

The reaction catalyst includes, for instance, triphenyl phosphine, triphenyl stibine, triethylamine, triethanolamine, tetramethylammonium chloride, or benzyltriethylammonium chloride. The acid catalyst can be used alone or in multiple combinations.

Based on a total usage amount of 100 parts by weight of the epoxy compound (a1) having at least two epoxy groups and the compound (a2) having at least one carboxylic acid group and at least one ethylenically unsaturated group, the usage amount of the reaction catalyst is preferably 0.01 parts by weight to 10 parts by weight, more preferably 0.3 parts by weight to 5 parts by weight.

Moreover, to control the degree of polymerization, a polymerization inhibitor can be added to the reaction solution. The polymerization inhibitor includes, for instance, methoxyphenol, methylhydroquinone, hydroquinone, 2,6-di-t-butyl-p-cresol, or phenothiazine. The polymerization inhibitor can be used alone or in multiple combinations.

Based on a total usage amount of 100 parts by weight of the epoxy compound (a1) having at least two epoxy groups and the compound (a2) having at least one carboxylic acid group and at least one ethylenically unsaturated group, the usage amount of the polymerization inhibitor is preferably 0.01 parts by weight to 10 parts by weight and more preferably 0.1 parts by weight to 5 parts by weight.

When preparing the first alkali-soluble resin (A-1), a polymerization solvent can optionally be used. The polymerization solvent includes an alcohol solvent such as ethanol, propanol, isopropanol, butanol, isobutanol, 2-butanol, hexanol, or ethylene glycol; a ketone solvent such as methyl ethyl ketone or cyclohexanone; an aromatic hydrocarbon solvent such as toluene or xylene; a cellosolve solvent such as cellosolve or butyl cellosolve; a carbitol solvent such as carbitol or butyl carbitol; a propylene glycol alkyl ether solvent such as propylene glycol monomethyl ether; a polypropylene glycol) alkyl ether solvent such as di(propylene glycol) methyl ether; an acetate solvent such as ethyl acetate, butyl acetate, ethylene glycol monoethyl ether acetate, or propylene glycol monomethyl ether acetate; an alkyl lactate solvent such as ethyl lactate or butyl lactate; or a dialkyl glycol ether solvent. The polymerization solvent can be used alone or in multiple combinations. Moreover, the acid value of the first alkali-soluble resin (A-1) is preferably 50 mgKOH/g to 200 mgKOH/g, more preferably 60 mgKOH/g to 150 mgKOH/g.

Based on a usage amount of 100 parts by weight of the alkai-soluble resin (A), the usage amount of the first alkali-soluble resin (A-1) can be 10 parts by weight to 80 parts by weight, preferably 15 parts by weight to 70 parts by weight, and more preferably 20 parts by weight to 50 parts by weight. When the alkali-soluble resin (A) contains the first alkali-soluble resin (A-1), the high-precision pattern linearity of the obtained photosensitive resin composition is better.

Moreover, The weight average molecular weight of the first alkali-soluble resin (A-1) in terms of polystyrene molecular weight as measured by GPC is preferably in the range of 800 to 8,000, more preferably 1,000 to 6,000.

### Second Alkali-Soluble Resin (A-2)

Preferably, the alkali-soluble resin (A) according to the invention further contains a second alkali-soluble resin (A-2), and the second alkali-soluble resin (A-2) is obtained from the copolymerization of an ethylenically unsaturated monomer containing one or more than one carboxylic acid groups and other copolymerizable ethylenically unsaturated monomers. Based on 100 parts by weight of the copolymerizing monomer, preferably, the second alkali-soluble resin (A-2) is obtained from the copolymerization of 5 parts by weight to 50 parts by weight of an ethylenically unsaturated monomer containing one or more than one carboxylic acid groups and 50 parts by weight to 95 parts by weight of other copolymerizable ethylenically unsaturated monomers.

The ethylenically unsaturated monomer containing one or more than one carboxylic acid groups can be used alone or in combination, and the ethylenically unsaturated monomer containing a carboxylic acid group contains, but is not limited to, an unsaturated monocarboxylic acid such as acrylic acid, methacrylic acid (MAA), butenoic acid, α-chloroacrylic acid, ethyl acrylic acid, cinnamic acid, 2-acryloylethoxy succinate, or 2-methacryloyloxyethyl succinate monoester (HOMS); an unsaturated dicarboxylic acid (anhydride) such as maleic acid, maleic anhydride, fumaric acid, itaconic acid, itaconic anhydride, citraconic acid, and citraconic anhydride; an unsaturated polycarboxylic acid (anhydride) of at least three carboxylic acid groups.

Preferably, the ethylenically unsaturated monomer containing a carboxylic acid group is selected from acrylic acid, methacrylic acid, 2-acryloylethoxy succinate, or 2-methacryloyloxyethyl succinate monoester. More preferably, the ethylenically unsaturated monomer containing a carboxylic acid group is selected from 2-acryloylethoxy succinate or 2-methacryloyloxyethyl succinate monoester, so that pigment dispersion can be increased, developing speed can be increased, and the generation of residue is reduced.

The other copolymerizable ethylenically unsaturated monomers can be used alone or in combination, and the other copolymerizable ethylenically unsaturated monomers contain, but are not limited to, aromatic vinyl group compounds such as styrene (SM), α-methylstyrene, vinyltoulene, chlorostyrene, and methoxystyrene; meleimides such as N-phenylmaleimide (PMI), N-o-hydroxyphenyl maleimide, N-m-hydroxyphenyl maleimide, N-p-hydroxyphenyl maleimide, N-o-methylphenyl maleimide, N-m-methylphenyl maleimide, N-p-methylphenyl maleimide,

N-o-methoxyphenyl maleimide, N-m-methylphenyl maleimide, N-p-methylphenyl maleimide, and N-cyclohexylmaleimide; unsaturated carboxylic acid esters such as methyl acrylate (MA), methyl methacrylate, ethyl acrylate, ethyl methacrylate, n-propyl acrylate, n-propyl methacrylate, iso-propyl acrylate, iso-propyl methacrylate, n-butyl acrylate, n-butyl methacrylate, iso-butyl acrylate, iso-butyl methacrylate, sec-butyl acrylate, sec-butyl methacrylate, t-butyl acrylate, t-butyl methacrylate, 2-hydroxyethyl acrylate, 2-hydroxyethyl methacrylate, 2-hydroxypropyl acrylate, 2-hydroxypropyl methacrylate, 3-hydroxypropyl acrylate, 3-hydroxypropyl methacrylate, 2-hydroxybutyl acrylate, 2-hydroxybutyl methacrylate, 3-hydroxybutyl acrylate, 3-hydroxybutyl methacrylate, 4-hydroxybutyl acrylate, 4-hydroxybutyl methacrylate, allyl acrylate, allyl methacrylate, benzyl acrylate, benzyl methacrylate (BzMA), phenyl acrylate, phenyl methacrylate, methoxy triethylene glycol acrylate, methoxy triethylene glycol methacrylate, lauryl methacrylate, tetradecyl methacrylate, cetylmethacrylate, octadecylmethacrylate, eicosylmethacrylate, docosylmethacrylate, and dicyclopentenyloxyethyl acrylate (DCPOA); N,N-dimethyl aminoethyl acrylate, N,N-dimethyl aminoethyl methacrylate, N,N-diethyl aminopropyl acrylate, N,N-dimethyl aminopropyl methacrylate, N,N-dibutyl aminopropyl acrylate, and N,t-butyl aminoethyl methacrylate; unsaturated carboxylic acid epoxypropyl esters such as epoxypropyl acrylate and epoxypropyl methacrylate; carboxylic acid vinyl esters such as vinyl acetate, vinyl propionate, and vinyl butyrate; unsaturated ethers such as methyl vinyl ether, ethyl vinyl ether, allyl glycidyl ether, and methallyl glycidyl ether; vinyl cyanide compounds such as acrylonitrile, methacrylonitrile, α-chloroacrylonitrile, and vinylidene cyanide; unsaturated amides such as acrylamide, methacrylamide, α-chloro acrylamide, N-hydroxyethyl acrylamide, and N-hydroxyethyl methacrylamide; aliphatic conjugated dienes such as 1,3-butadiene, isoamylene, and chlorinated butadiene.

Preferably, the other copolymerizable ethylenically unsaturated monomers are selected from styrene, N-phenylmaleimide, methyl acrylate, methyl methacrylate, 2-hydroxyethyl acrylate, 2-hydroxyethyl methacrylate, acrylic acid benzyl ester, benzyl methacrylate, dicyclopentenyloxyethyl acrylate, or a combination thereof.

When preparing the second alkali-soluble resin (A-2), a solvent can be used, wherein the solvent can be used alone or in combination, and the solvent contains, but is not limited to, a (poly)alkylene glycol monoalkyl ether such as ethylene glycol monomethyl ether, ethylene glycol monoethyl ether, diethylene glycol monomethyl ether, diethylene glycol monoethyl ether, diethylene glycol n-propyl ether, diethylene glycol n-butyl ether, triethylene glycol monomethyl ether, triethylene glycol monoethyl ether, propylene glycol monomethyl ether, propylene glycol monoethyl ether, dipropylene glycol monomethyl ether, dipropylene glycol monoethyl ether, dipropylene glycol n-propyl ether, dipropylene glycol n-butyl ether, tripropylene glycol monoethyl ether, or tripropylene glycol monoethyl ether; a (poly)alkylene glycol monoalkyl ether acetate such as ethylene glycol monomethyl ether acetate, ethylene glycol monoethyl ether acetate, propylene glycol monomethyl ether acetate (PGMEA), or propylene glycol monoethyl ether acetate; other ethers such as diethylene glycol dimethyl ether, diethylene glycol methyl ethyl ether, diethylene glycol diethyl ether, and tetrahydrofuran; a ketone such as methyl ethyl ketone, cyclohexanone, 2-heptanone, or 3-heptanone; an alkyl lactate such as methyl 2-hydroxypropanoate or ethyl 2-hydroxypropanoate; other esters such as methyl 2-hydroxy-2-methylpropanoate, ethyl 2-hydroxy-2-methylpropanoate, methyl 3-methoxypropanoate, ethyl 3-methoxypropanoate, methyl 3-ethoxypropanoate, ethyl 3-ethoxypropanoate (EEP), ethyl ethoxyacetate, ethyl hydroxyacetate, methyl 2-hydroxy-3-methylenebutyrate, 3-methyl-3-methoxybutyl acetate, 3-methyl-3-methoxybutyl propanoate, ethyl acetate, n-propyl acetate, isopropyl acetate, n-butyl acetate, isobutyl acetate, n-amyl acetate, isoamyl acetate, n-butyl propanoate, ethyl butyrate, n-propyl butyrate, isopropyl butyrate, n-butyl butyrate, methyl pyruvate, ethyl pyruvate, n-propyl pyruvate, methyl acetoacetate, ethyl acetoacetate, and ethyl 2-oxybutyrate; an aromatic hydrocarbon such as toluene or xylene; or an amine such as N-methylpyrrolidone, N,N-dimethylformamide, or N,N-dimethylacetamide. Preferably, the solvent is selected from PGMEA, EEP, or a combination thereof. The (poly)alkylene glycol monoalkyl ether refers to alkylene glycol monoalkyl ether or polyalkylene glycol monoalkyl ether. The (poly)alkylene glycol monoalkyl ether acetate refers to alkylene glycol monoalkyl ether acetate or polyalkylene glycol monoalkyl ether acetate.

The initiator used in the preparation of the second alkali-soluble resin (A-2) is generally a free-radical polymerization initiator, and specific examples include, for instance: an azo compound such as 2,2′-azobisisobutyronitrile, 2,2′-azobis(2,4-dimethylvaleronitrile), 2,2′-azobis(4-methoxy-2,4-dimethylvaleronitrile), or 2,2′-azobis-2-methyl butyronitrile (AMBN); and a peroxy compound such as benzoyl peroxide.

Based on a usage amount of 100 parts by weight of the alkai-soluble resin (A), the usage amount of the second alkali-soluble resin (A-2) can be 20 parts by weight to 90 parts by weight, preferably 30 parts by weight to 85 parts by weight, and more preferably 50 parts by weight to 80 parts by weight.

Moreover, the weight average molecular weight of the second alkali-soluble resin (A-2) in terms of polystyrene molecular weight as measured by GPC is preferably in the range of 3,000 to 30,000, more preferably 5,000 to 25,000.

### Compound (B) Containing an Ethylenically Unsaturated Group

The compound (B) containing an ethylenically unsaturated group includes at least one compound (B-1) selected from the group consisting of a compound represented by formula (5) and a compound represented by formula (6). Moreover, the compound (B) containing an ethylenically unsaturated group can further optionally include other compounds (B-2) containing an ethylenically unsaturated group.

### Compound (B-1)

The compound (B-1) is at least one selected from the group consisting of a compound represented by formula (5) and a compound represented by formula (6). Specifically, the compounds represented by formula (5) and formula (6) are as follows.

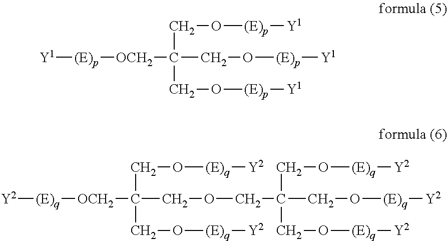

In formula (5) and formula (6), E each independently represent —((CH2)_{z}CH₂O)— or —((CH₂)_{z}CH(CH₃)O)—, z each independently represent an integer of 1 to 10, Y₁ and Y₂ each independently represent an acryl group, a methacryl group, a hydrogen atom, or a carboxylic group; in formula (5), the sum of the acryl group and the methacryl group represented by Y¹ is 3 or 4, p each independently represent an integer of 0 to 10, the sum of each p is an integer of 1 to 40; in formula (6), the sum of the acryl group and the methacryl group represented by Y² is 5 or 6, q each independently represent an integer of 0 to 10, and the sum of each q is an integer of 1 to 60.

The compound represented by formula (5) or the compound represented by formula (6) can be synthesized via, for instance, the following known steps: a step in which pentaerythritol or dipentaerythritol is bonded to an open-ring skeleton via the ring-opening addition reaction of ethylene oxide or propylene oxide; and a step in which, for instance, (meth)acryloyl chloride and the terminal hydroxyl group of the open-ring skeleton are reacted so that a (meth)acryloyl group is introduced. Each step is commonly known, and those having ordinary skill in the art can readily synthesize the compound represented by formula (5) or the compound represented by formula (6).

The compound represented by formula (5) and the compound represented by formula (6) are preferably a pentaerythritol derivative and/or a dipentaerythritol derivative.

Specific examples of the compound represented by formula (5) include a compound represented by formula (7), ethoxylated pentaerythritol tetraacrylate, propoxylated pentaerythritol tetraacrylate, or a combination thereof.

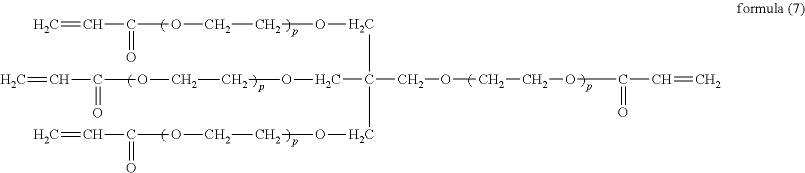

In formula (7), each p sums to 4 or 12.

Specific examples of the compound represented by formula (6) include compounds represented by formula (8) to formula (10), wherein each q in formula (8) sums to 6 or 12; each q in formula (9) sums to 12; each q in formula (10) sums to 6; and formula (8) is preferred.

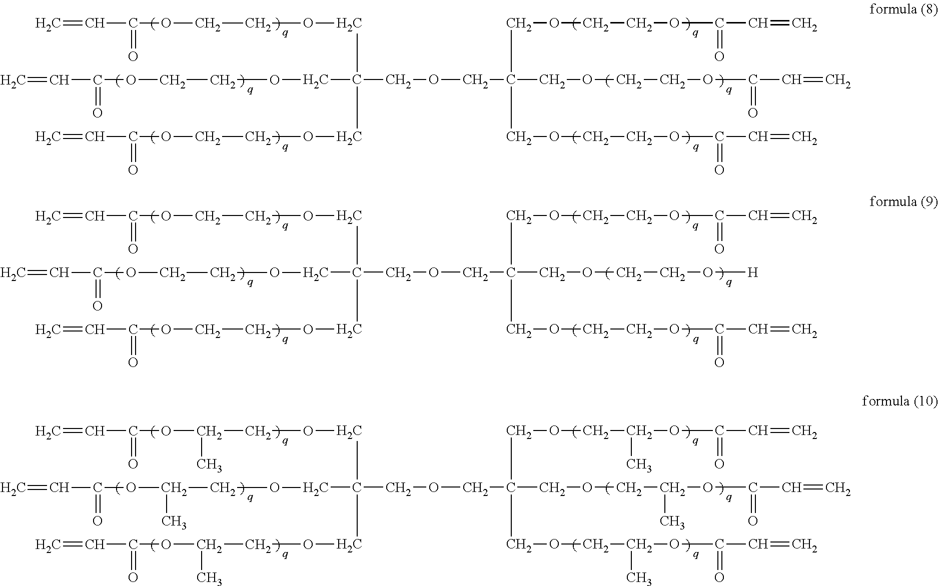

### Compound (B-2)

The other compounds (B-2) containing an ethylenically unsaturated group contain a compound selected from the group consisting of a (meth)acrylate compound (B-2-i) obtained by reacting caprolactone-modified polyalcohol and (meth)acrylic acid and a compound (B-2-ii) having the functional group shown in formula (11).

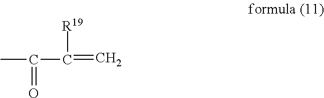

In formula (11), R¹⁹ represents hydrogen or a methyl group.

The caprolactone-modified polyol is obtained by reacting caprolactone and a polyol having at least 4 functional groups. Specific examples of the caprolactone include, for instance, γ-carpolactone, δ-carpolactone, or ε-carpolactone; preferably ε-carpolactone; and the polyalcohol having four or more functional groups can include, for instance, pentaerythritol, di(trimethylolpropane), or dipentaerythritol.

Specific examples of the (meth)acrylate compound (B-2-i) can include: a pentaerythritol caprolactone-modified tetra(meth)acrylate compound, a di(trimethylolpropane) caprolactone-modified tetra(meth)acrylate compound, and a dipentaerythritol caprolactone-modified poly(meth)acrylate compound. In particular, specific examples of the dipentaerythritol caprolactone-modified poly(meth)acrylate compound include a dipentaerythritol caprolactone-modified di(meth)acrylate compound, a dipentaerythritol caprolactone-modified tri(meth)acrylate compound, a dipentaerythritol caprolactone-modified tetra(meth)acrylate compound, a dipentaerythritol caprolactone-modified penta(meth)acrylate compound, and a dipentaerythritol caprolactone-modified hexa(meth)acrylate compound.

More specifically, the structure of the dipentaerythritol caprolactone-modified poly(meth)acrylate can be represented by formula (12):

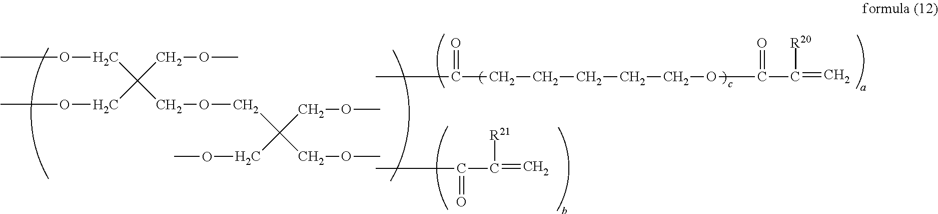

In formula (12), R²⁰ and R²¹ respectively represent hydrogen or a methyl group; c is an integer of 1 to 2; a is an integer of 1 to 6; and b is an integer of 0 to 5. In particular, a+b=2 to 6; preferably a+b=3 to 6; more preferably a+b=5 to 6; and most preferably a+b=6.

The compound (B-2-ii) having the functional group shown in formula (11) can include, for instance: acrylamide, (meth)acryloylmorpholine, 7-amino-3,7-dimethyloctyl (meth)acrylate, iso-butoxymethyl(meth)acrylamide, iso-bornyloxy ethyl(meth)acrylate, iso-bornyl(meth)acrylate, 2-ethylhexyl(meth)acrylate, ethyl diethylene glycol(meth)acrylate, t-octyl(meth)acrylamide, diacetone(meth)acrylamide, dimethylamino (meth)acrylate, dodecyl(meth)acrylate, dicyclopentenyloxyethyl(meth)acrylate, dicyclopentenyl (meth)acrylate, N,N-dimethyl(meth)acrylamide, tetrachlorophenyl(meth)acrylate, 2-tetrachlorophenoxyethyl (meth)acrylate, tetrahydrofurfuryl(meth)acrylate, tetrabromophenyl(meth)acrylate, 2-tetrabromophenoxyethyl(meth)acrylate, 2-trichlorophenoxyethyl(meth)acrylate, tribromo phenyl(meth)acrylate, 2-tribromophenoxyethyl(meth)acrylate, 2-hydroxyethyl(meth)acrylate, 2-hydroxypropyl(meth)acrylate, vinylcaprolactam, N-vinylpyrrolidone, phenoxyethyl (meth)acrylate, pentachlorophenyl(meth)acrylate, pentabromophenyl(meth)acrylate, polyethylene glycol mono(meth)acrylate, polypropylene glycol mono(meth)acrylate, bornyl(meth)acrylate, ethylene glycol di(meth)acrylate, dicyclopentenyl di(meth)acrylate, triethylene glycol di(meth)acrylate, tetraethylene glycol di(meth)acrylate, tri(2-hydroxyethyl) isocyanurate di(meth)acrylate, tri(2-hydroxyethyl) isocyanurate tri(meth)acrylate, caprolactone-modified tri(2-hydroxyethyl) isocyanurate tri(meth)acrylate, trimethylolpropyl tri(meth)acrylate, triethylene glycol di(meth)acrylate, neo-pentylene glycol di(meth)acrylate, 1,4-butanediol di(meth)acrylate, 1,6-hexanediol di(meth)acrylate, pentaerythritol tri(meth)acrylate, pentaerythritol tetra(meth)acrylate, polyester di(meth)acrylate, polyethylene glycol di(meth)acrylate, dipentaerythritol hexa(meth)acrylate, dipentaerythritol penta(meth)acrylate, dipentaerythritol tetra(meth)acrylate, ditrimethylolpropyl tetra(meth)acrylate, EO-modified bisphenol A di(meth)acrylate, PO-modified bisphenol A di(meth)acrylate, EO-modified hydrogenated bisphenol A di(meth)acrylate, PO-modified hydrogenated bisphenol A di(meth)acrylate, EO-modified bisphenol F di(meth)acrylate, or phenolic polyglycidyl ether(meth)acrylate.

The compound (B-2-ii) having the functional group represented by formula (11) is preferably selected from the group consisting of trimethylolpropyl triacrylate, pentaerythritol triacrylate, pentaerythritol tetraacrylate, dipentaerythritol hexaacrylate, dipentaerythritol pentaacrylate, dipentaerythritol tetraacrylate, ditrimethylolpropyl tetraacrylate, and a combination thereof.

When the compound (B) containing an ethylenically unsaturated group contained in the photosensitive resin composition of the invention contains at least one compound (B-1) selected from the group consisting of the compound represented by formula (5) and the compound represented by formula (6), the development properties are better.

In the photosensitive resin composition of the invention, based on 100 parts by weight of the alkali-soluble resin (A), the usage amount of the at least one compound (B-1) selected from the group consisting of the compound represented by formula (5) and the compound represented by formula (6) is 10 parts by weight to 100 parts by weight, preferably 15 parts by weight to 80 parts by weight, and more preferably 20 parts by weight to 60 parts by weight.

In the photosensitive resin composition of the invention, based on 100 parts by weight of the alkali-soluble resin (A), the usage amount of the compound (B) containing an ethylenically unsaturated group is 60 parts by weight to 600 parts by weight, preferably 80 parts by weight to 500 parts by weight, and more preferably 100 parts by weight to 400 parts by weight.

### Photoinitiator (C)

The photoinitiator (C) is at least one selected from the group consisting of an acetophenone compound, a biimidazole compound, and an acyl oxime compound.

Specific examples of the acetophenone compound include: p-dimethyl amino-acetophenone, α,α′-dimethoxyazoxy-acetophenone, 2,2′-dimethyl-2-phenyl-acetophenone, p-methoxy-acetophenone, 2-methyl-1-(4-methylthiophenyl)-2-morpholino-l-propanone, and 2-benzyl-2-N,N-dimethylamino-1-(4-morpholinophenyl) -1-butanone.

Specific examples of the biimidazole compound include: 2,2′-bis(o-chlorophenyl)-4,4′,5,5′-tetraphenyl-biimidazole, 2,2′-bis(o-fluorophenyl)-4,4′,5,5′-tetraphenyl-biimidazole, 2,2′-bis(o-methylphenyl)-4,4′,5,5 ′-tetraphenyl-biimidazole, 2,2′-bis(o-methoxyphenyl)-4,4′,5,5′-tetraphenyl-biimidazole, 2,2′-bis(o-ethylphenyl)-4,4′,5,5′-tetraphenyl-biimidazole, 2,2′-bis(p-methoxyphenyl)-4,4′,5,5′-tetraphenyl-biimidazole, 2,2′-bis (2,2′,4,4′-tetramethoxyphenyl)-4,4′,5,5′-tetraphenyl-biimidazole, 2,2′-bis(2-chlorophenyl) -4,4′,5,5′-tetraphenyl-biimidazole, and 2,2′-bis(2,4-dichlorophenyl)-4,4′,5,5′-tetraphenyl -biimidazole.

Specific examples of the acyl oxime compound include: ethanone,1-[9-ethyl-6-(2-methylbenzoyl)-9H-carbazole-3-yl]-,1-(O-acetyl oxime), trade name: CGI-242, manufactured by Ciba Specialty Chemicals, and having the structure shown in formula (13), 1-(4-phenyl-thio-phenyl)-octane-1,2-dion 2-oxime-O-benzoate, trade name: CGI-124, manufactured by Ciba Specialty Chemicals, and having the structure shown in formula (14), and ethanone,1-[9-ethyl-6-(2-chloro-4-benzyl-thio-benzoyl)-9H-carbazole-3-yl]-,1-(O-acetyl oxime) manufactured by Asahi Denka Co., Ltd. having the structure shown in formula (15).

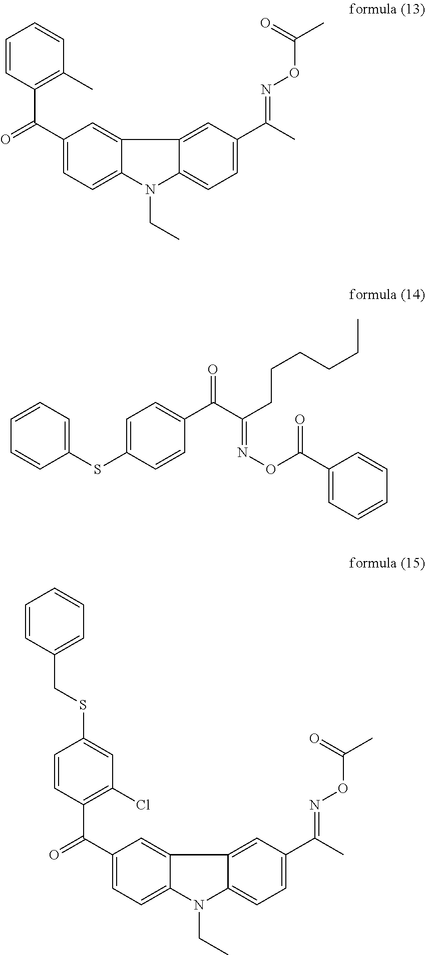 [SMILES: CCn1c2ccc(C(=O)c3ccccc3C)cc2c2cc(/C(C)=N/OC(C)=O)ccc21 ; CCCCCC/C(=N\OC(=O)c1ccccc1)C(=O)c1ccc(Sc2ccccc2)cc1 ; CCn1c2ccc(C(=O)c3ccc(SCc4ccccc4)cc3Cl)cc2c2cc(/C(C)=N/OC(C)=O)ccc21]

The photoinitiator (C) is preferably 2-methyl-1-(4-methylthiophenyl)-2-morpholino-1-propanone, 2-benzyl-2-N,N-dimethylamino-1-(4-morpholinophenyl)-1-butanone, 2,2′-bis(o-chlorophenyl)-4,4′,5,5 ′-tetraphenylbiimidazole, ethanone,1-[9-ethyl-6-(2-methylbenzoyl)-9H-carbazole-3-yl]-,1-(O-acetyl oxime), or a combination of the compounds.

The photoinitiator (C) can further include the following compounds as needed: a benzophenone compound such as thioxanthone, 2,4-diethyl-thioxanthanone, thioxanthone-4-sulfone, benzophenone, 4,4′-bis(dimethylamino)benzophenone, or 4,4′-bis(diethylamino)benzophenone; an α-diketone such as benzil or acetyl; an acyloin such as benzoin; an acyloin ether such as benzoin methylether, benzoin ethylether, or benzoin isopropyl ether; an acylphosphineoxide such as 2,4,6-trimethyl-benzoyl-diphenyl-phosphineoxide or bis-(2,6-dimethoxy-benzoyl)-2,4,4-trimethyl-benzyl-phosphineoxide; a quinone such as anthraquinone or 1,4-naphthoquinone; a halide such as phenacyl chloride, tribromomethyl-phenylsulfone, or tris(trichloromethyl)-s-triazine; and a peroxide such as di-tertbutylperoxide; wherein a benzophenone compound is preferred; and 4,4′-bis(diethylamino)benzophenone is most preferred.

In the photosensitive resin composition of the invention, based on 100 parts by weight of the alkali-soluble resin (A), the usage amount of the photoinitiator (C) is 20 parts by weight to 200 parts by weight, preferably 40 parts by weight to 150 parts by weight, and more preferably 50 parts by weight to 100 parts by weight.

### Organic Solvent (D)

The organic solvent (D) needs to be able to dissolve the alkali-soluble resin (A), the compound (B) containing an ethylenically unsaturated group, and the photoinitiator (C), not react with the components, and have suitable volatility.

The organic solvent (D) can include: a (poly)alkylene glycol monoalkyl ether such as ethylene glycol monomethyl ether, ethylene glycol monoethyl ether, diethylene glycol monomethyl ether, diethylene glycol monoethyl ether, diethylene glycol n-propyl ether, diethylene glycol n-butyl ether, triethylene glycol monomethyl ether, triethylene glycol monoethyl ether, propylene glycol monomethyl ether, propylene glycol monoethyl ether, dipropylene glycol monomethyl ether, dipropylene glycol monoethyl ether, dipropylene glycol n-propyl ether, dipropylene glycol n-butyl ether, tripropylene glycol monoethyl ether, or tripropylene glycol monoethyl ether; a (poly)alkylene glycol monoalkyl ether acetate such as ethylene glycol monomethyl ether acetate, ethylene glycol monoethyl ether acetate, propylene glycol monomethyl ether acetate, or propylene glycol monoethyl ether acetate; other ethers such as diethylene glycol dimethyl ether, diethylene glycol methyl ethyl ether, diethylene glycol diethyl ether, and tetrahydrofuran; a ketone such as methyl ethyl ketone, cyclohexanone, 2-heptanone, or 3-heptanone; an alkyl lactate such as methyl 2-hydroxypropanoate or ethyl 2-hydroxypropanoate; other esters such as methyl 2-hydroxy-2-methylpropanoate, ethyl 2-hydroxy-2-methylpropanoate, methyl -methoxypropanoate, ethyl 3-methoxypropanoate, methyl 3-ethoxypropanoate, ethyl 3-ethoxypropanoate (EEP), ethyl ethoxyacetate, ethyl hydroxyacetate, methyl 2-hydroxy-3-methylenebutyrate, 3-methyl-3-methoxybutyl acetate, 3-methyl-3-methoxybutyl propanoate, ethyl acetate, n-propyl acetate, isopropyl acetate, n-butyl acetate, isobutyl acetate, n-amyl acetate, isoamyl acetate, n-butyl propanoate, ethyl butyrate, n-propyl butyrate, isopropyl butyrate, n-butyl butyrate, methyl pyruvate, ethyl pyruvate, n-propyl pyruvate, methyl acetoacetate, ethyl acetoacetate, and ethyl 2-oxybutyrate; an aromatic hydrocarbon such as toluene or xylene; or a carboxylic amine such as N-methylpyrrolidone, N,N-dimethylformamide, or N,N-dimethylacetamide. Preferably, the solvent is selected from PGMEA and EEP, and the solvent can be used alone or in multiple combinations.

In the photosensitive resin composition of the invention, based on 100 parts by weight of the alkali-soluble resin (A), the usage amount of the organic solvent (D) is 500 parts by weight to 5000 parts by weight, preferably 600 parts by weight to 4000 parts by weight, and more preferably 700 parts by weight to 3000 parts by weight.

### Compound (E)

The compound (E) is as shown in the following formula (1):

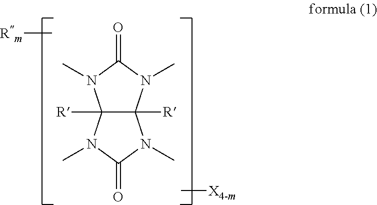

In formula (1), R′ each independently represent a hydrogen atom, a C₁ to C₂₀ substituted or unsubstituted hydrocarbon group or acyl group, R″ each independently represent a hydrogen atom, a C₁ to C15 substituted or unsubstituted hydrocarbon group, acyl group, or nitro group, m represents an integer of 0, 1, or 2, and X is a group having a structure represented by formula (2):

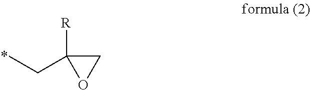

In formula (2), R represents a hydrogen atom or a C₁ to C₄ alkyl group.

The substituent X and the R″ group are located at one of the replacement locations of the four N's in formula (1). For instance, when m=2, two substituents X can respectively be located on two of the N's, such as two substituents X are located at the 1,3 position on the same five-membered ring or not located at the 1,5 position or the 1,7 position of the same five-membered ring. A preferred disposition of the substituent X is at least two substituents X located at the 1,3 position, the 1,3,5 position, the 1,3,7 position, or the 1,3,5,7 position on the same five-membered ring.

The substituent R′ can each independently represent a hydrogen atom, or a C₁ to C20 substituted or unsubstituted hydrocarbon group or acyl group. The upper limit of the number of carbons of the hydrocarbon group or the acyl group is preferably 15, more preferably 12, even more preferably 10, still more preferably 8, and can even be 4.

The hydrocarbon group or the acyl group used as the substituent R′ can be straight-chained or branched, and a group containing an alkenyl group, a cycloalkyl group, a cycloalkenyl group, or an aromatic group can also be used. When the substituent R′ is a cycloalkyl group, a cycloalkenyl group, or an aromatic group, R′ is preferably a monocyclic group such as a monocyclic aromatic group such as a phenyl group, a benzyl group, a tolyl group, or a xylyl group, or a monocyclic cycloalkyl group such as a cyclopentyl group or a cyclohexyl group.

A portion of the hydrogen atoms on the hydrocarbon group or the acyl group used as the substituent R′ may be substituted by heteroatoms or substituents, such as a halogen atom such as chlorine or bromine, or a substituent such as an alkoxy group, an acyl group, or an acyloxy group. When the substituent R′ is a cyclic group, the ring of the cyclic group can also contain a heteroatom such as an oxygen, nitrogen, or sulfur atom, and the substituent R′ of the cyclic group preferably contains 1 to 3 heteroatoms.

When the substituent R′ has a branched hydrocarbon group as a substituent, the upper limit of carbon atoms of the hydrocarbon group is preferably 10, more preferably 8; even more preferably 6, and can even be 4. The branched hydrocarbon group used as the substituent can further contain a group such as halogen, an aromatic group, a cycloalkyl group, or a cyclic group having 1 to 3 heteroatoms.

The upper limit of the total number of carbon atoms of all of the substituents R′ is preferably 12, more preferably 10. The upper limit of the number of carbon atoms of a single substituent R′ is preferably 8, more preferably 6, and even more preferably 4. 101101 The substituent R″ can each independently represent a hydrogen atom, or a C₁ to C15 substituted or unsubstituted hydrocarbon group, acyl group, or nitro group. When the substituent R″ is a hydrocarbon group, the upper limit of the number of carbon atoms of the substituent R″ is preferably 12, more preferably 10, and even more preferably 8.

Similar to the substituent R′, the hydrocarbon group or the acyl group used as the substituent R″ can be straight-chained or branched, and a group containing an alkenyl group, a cycloalkyl group, a cycloalkenyl group, or an aromatic group can also be used. When the substituent R″ is a cycloalkyl group, a cycloalkenyl group, or an aromatic group, R″ is preferably a monocyclic group. A portion of the hydrogen atoms on the hydrocarbon group or the acyl group of the substituent R″ may be substituted by heteroatoms or substituents. When the substituent R″ is a cyclic group, the ring of the cyclic group can also contain a heteroatom, and preferably can contain 1 to 3 heteroatoms.

Specific examples of the substituent on the substituent R″ include, for instance, halogen, a hydroxyl group, an amine group, an N-substituted amine group, a thiol group, an alkylthio group, an arylthio group, an alkoxy group, an aryloxy group, or an acyloxy group. The substituent R″ can contain one or more substituents, preferably 1 to 3. In a more preferred specific example, the substituent R″ can contain an alkyl group, and the limit of the number of carbons thereof is the same as for the substituent R′.

Table 1 lists preferred examples of the compound (E) shown in formula (1). The definitions of R″ and m are the same for formula (1), and R′₁ and R′₂ respectively represent two substituents R′ in formula (1).

TABLE 1

| R″ | m | R′₁ | R′₂ |
|---|---|---|---|
| —CH₃ | 2 | —H | —H |
| —NO₂ | 2 | —H | —H |
| — | 0 | —CH₃ | —CH₃ |
| — | 0 | —H | —CH₃ |
| — | 0 | —H | —H |
| —COCH₃ | 2 | —CH₃ | —CH₃ |
| —COC₂H₅ | 2 | —CH₃ | —CH₃ |
| —COC₃H₇ | 2 | —CH₃ | —CH₃ |
| —CH₃ | 2 | —CH₃ | —CH₃ |
| —CH₃ | 2 | —C₆H₅ | —C₆H₅ |
| —COCH₃ | 2 | —C₆H₅ | —C₆H₅ |
| — | 0 | —C₆H₅ | —C₆H₅ |
| —COC₂H₅ | 2 | —C₆H₅ | —C₆H₅ |
| —COC₃H₇ | 2 | —C₆H₅ | —C₆H₅ |
| —CH₃ | 1 | —H | —H |
| —CH₃ | 1 | —H | —COCH₃ |
| —COH | 1 | —H | —H |
| —CH₂C₆H₅ | 2 | —H | —H |
| —COCH₃ | 2 | —H | —H |
| —COC₂H₅ | 2 | —H | —H |
| —COC₃H₇ | 2 | —H | —H |
| —CH₂CH(OH)CH₂(OH) | 1 | —H | —H |
| —CH(OH)(CH₂)₂N(C₂H₅)₂ | 1 | —H | —H |
| —CH(OH)(CH₂)₂N(CH₃)₂ | 1 | —H | —H |

When the photosensitive resin composition of the invention does not contain the compound (E) represented by formula (1), the high-precision pattern linearity and the development properties of the obtained photosensitive resin composition are poor.

In the photosensitive resin composition of the invention, based on 100 parts by weight of the alkali-soluble resin (A), the usage amount of the compound (E) represented by formula (1) is 3 parts by weight to 30 parts by weight, preferably 5 parts by weight to 25 parts by weight, and more preferably 8 parts by weight to 20 parts by weight.

When the usage amount of the compound (E) represented by formula (1) is within the above range, a photosensitive resin composition having better precision pattern linearity can subsequently be obtained, and development properties can further be improved.

### Pigment (F)

The photosensitive resin composition of the invention can also contain a pigment (F). The pigment (F) is at least one selected from the group consisting of an inorganic pigment and an organic pigment.

The inorganic pigment contains a metal compound such as a metal oxide or a metallic complex salt, such as: a metal oxide of iron, cobalt, aluminum, cadmium, lead, copper, titanium, magnesium, chromium, zinc, or antimony, and a complex oxide of the metals.

The organic pigment can include, for instance, C. I. pigment yellow 1, 3, 11, 12, 13, 14, 15, 16, 17, 20, 24, 31, 53, 55, 60, 61, 65, 71, 73, 74, 81, 83, 93, 95, 97, 98, 99, 100, 101, 104, 106, 108, 109, 110, 113, 114, 116, 117, 119, 120, 126, 127, 128, 129, 138, 139, 150, 151, 152, 153, 154, 155, 156, 166, 167, 168, 175; C. I. pigment orange 1, 5, 13, 14, 16, 17, 24, 34, 36, 38, 40, 43, 46, 49, 51, 61, 63, 64, 71, 73; C. I. pigment red 1, 2, 3, 4, 5, 6, 7, 8, 9, 10, 11, 12, 14, 15, 16, 17, 18, 19, 21, 22, 23, 30, 31, 32, 37, 38, 40, 41, 42, 48:1, 48:2, 48:3, 48:4, 49:1, 49:2, 50:1, 52:1, 53:1, 57, 57:1, 57:2, 58:2, 58:4, 60:1, 63:1, 63:2, 64:1, 81:1, 83, 88, 90:1, 97, 101, 102, 104, 105, 106, 108, 112, 113, 114, 122, 123, 144, 146, 149, 150, 151, 155, 166, 168, 170, 171, 172, 174, 175, 176, 177, 178, 179, 180, 185, 187, 188, 190, 193, 194, 202, 206, 207, 208, 209, 215, 216, 220, 224, 226, 242, 243, 245, 254, 255, 264, 265; C. I. pigment violet 1, 19, 23, 29, 32, 36, 38, 39; C. I. pigment blue 1, 2, 15, 15:3, 15:4, 15:6, 16, 22, 60, 66; C. I. pigment green 7, 36, 37; C. I. pigment brown 23, 25, 28, or C. I. pigment black 1, 7. Specific examples of the black pigment can further contain black organic pigments such as perylene black, cyanine black, or aniline black; a near-black mixture of organic pigments obtained by mixing two or more pigments selected from the pigments of, for instance, red, blue, green, purple, yellow, cyanine, or magenta; light-shielding materials such as carbon black, chromium oxide, ferric oxide, titanium black, or graphite.

In the photosensitive resin composition of the invention, based on 100 parts by weight of the alkali-soluble resin (A), the usage amount of the pigment (F) is 40 parts by weight to 400 parts by weight, preferably 50 parts by weight to 350 parts by weight, and more preferably 60 parts by weight to 300 parts by weight.

### Dye (G)

The dye (G) contains a red dye having the structure of formula (16):

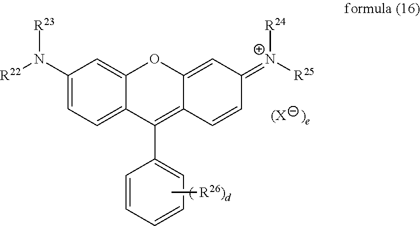

In formula (16), R²² to R²⁵ each independently represent hydrogen, —R²⁷, a C₆ to C₁₀ aromatic hydrocarbon group, or a C₆ to C₁₀ aromatic hydrocarbon group substituted by a halogen atom, —R²⁷, —OH, —OR²⁷, —SO₃⁻, —SO₃H, —SO₃M, —COOH, —COOR²⁷, —SO₃R²⁷, —SO₂NHR²⁸, or —SO₂NR²⁸R²⁹. R²⁶ each independently represent —SO₃⁻, —SO₃H, —SO₃M, —COOH, —COOR²⁷, —SO₃R²⁷, —SO₂NHR²⁸, or —SO₂NR²⁸R²⁹. d represents an integer of 0 to 5. X represents a halogen atom. e represents 0 or 1.

R²⁷ represents a C₁ to C₁₀ alkyl group that can be substituted by a halogen atom, wherein —CH₂— in the alkyl group can be replaced by —O—, a carbonyl group, or —NR³⁰—.

R³⁰ represents a C₁ to C₁₀ alkyl group that can be substituted by a halogen atom.

R²⁸ and R²⁹ each independently represent a C₁ to C₁₀ straight-chain or branched alkyl group, a C₃ to C₃₀ cycloalkyl group, or -Q; wherein the hydrogen atom in the alkyl group or the cycloalkyl group can be substituted by a substituent, the substituent is selected from the group consisting of a hydroxyl group, a halogen atom, -Q, —CH═Ch₂, and —CH═CH—R²⁷; —CH₂— the alkyl group or the cycloalkyl group can be replaced by —O—, a hydroxyl group, or —NR³⁰—; or R²⁸ and R²⁹ are combined to form a C₁ to C₁₀ heterocyclic group, and the hydrogen atom in the heterocyclic group can be substituted by —R²⁷, —OH, or -Q. Q represents a C₆ to C₁₀ aromatic hydrocarbon group, a C₅ to C₁₀ heteroaromatic group, a C₆ to C₁₀ aromatic hydrocarbon group substituted by a halogen atom, —R²⁷, —OH, —OR²⁷, —NO₂, —CH═CH₂, or —CH═CH—R²⁷, or a C₅ to C₁₀ heteroaromatic hydrocarbon group substituted by a halogen atom, —R²⁷, —OH, —OR²⁷, —NO₂, —CH═CH₂, or —CH═CH—R²⁷. M represents potassium or sodium.

R²⁷ can include: a methyl group, an ethyl group, a propyl group, an isopropyl group, a butyl group, an isobutyl group, a pentyl group, an isopentyl group, a neopentyl group, a cyclopentyl group, a hexyl group, a cyclohexyl group, a heptyl group, a cycloheptyl group, an octyl group, a cyclooctyl group, a 2-ethylhexyl group, a nonyl group, a decyl group, a tricyclo(5.3.0.03,10)decanyl group, a methoxypropyl group, a hexyloxypropyl group, a 2-ethylhexyloxypropyl group, a methoxyhexyl group, or an epoxypropyl group.

The C₆ to C₁₀ aromatic hydrocarbon group preferably can include, for instance: a phenyl group or a naphthyl group.

—SO₃R²⁷ preferably includes: methanesulfonyl, ethanesulfonyl, hexanesulfonyl, or decanesulfonyl.

—COOR²⁷ preferably includes: methyloxycarbonyl, ethyloxycarbonyl, propoxy carbonyl, isopropoxycarbonyl, butoxycarbonyl, isobutoxycarbonyl, pentyloxycarbonyl, isopentyloxycarbonyl, neopentyloxycarbonyl, cyclopentyloxycarbonyl, hexyloxycarbonyl, cyclohexyloxycarbonyl, heptoxycarbonyl, cycloheptyloxycarbonyl, octyloxycarbonyl, cyclooctyloxycarbonyl, 2-ethylhexyloxycarbonyl, nonyloxycarbonyl, decyloxycarbonyl, tricyclo[5.3.0.0^{3,10}]decylcarbonyl, methoxypropoxycarbonyl, hexyloxypropoxycarbonyl, 2-ethylhexyloxypropoxycarbonyl, or methoxyhexyloxycarbonyl.

—SO₂NHR²⁸ preferably includes: sulfamoyl, methylsulfamoyl, ethylsulfamoyl, propylsulfamoyl, isopropylsulfamoyl, butylsulfamoyl, isobutylsulfamoyl, pentylsulfamoyl, isopentylsulfamoyl, neopentylsulfamoyl, cyclopentylsulfamoyl, hexylsulfamoyl, cyclohexyl sulfamoyl, heptylsulfamoyl, cycloheptylsulfamoyl, octylsulfamoyl, cyclooctylsulfamoyl, 2-ethylhexylsulfamoyl, nonylsulfamoyl, decylsulfamoyl, tricyclo[5.3.0.0^{3,10}]decylsulfamoyl, methoxypropylsulfamoyl, hexyloxypropylsulfamoyl, 2-ethylhexyloxypropylsulfamoyl, methoxyhexylsulfamoyl, epoxypropylsulfamoyl, 1,5-dimethylhexylsulfamoyl, propoxypropyl sulfamoyl, isopropoxypropylsulfamoyl, 3-phenyl-1-methylpropylsulfamoyl,

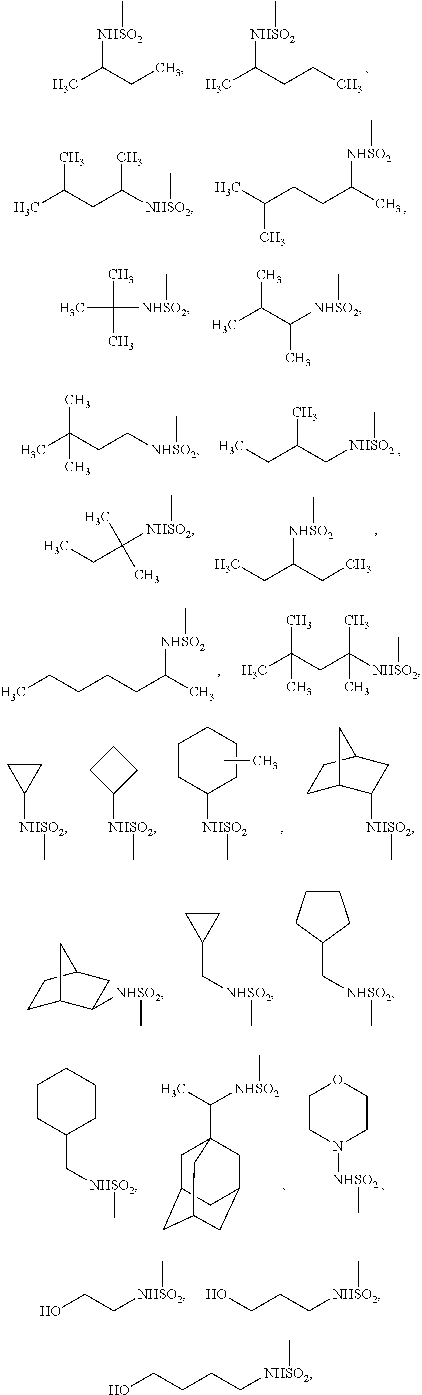

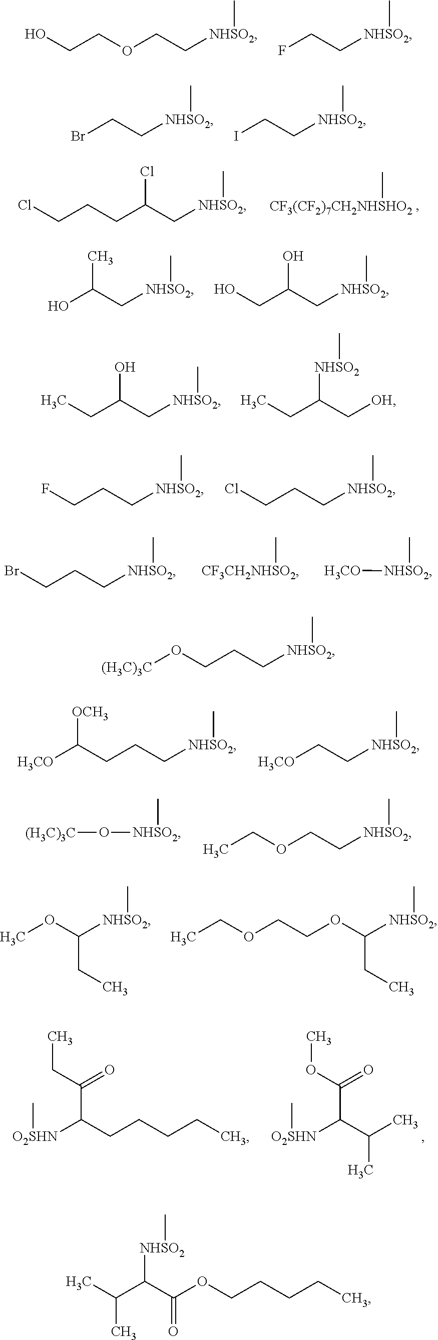

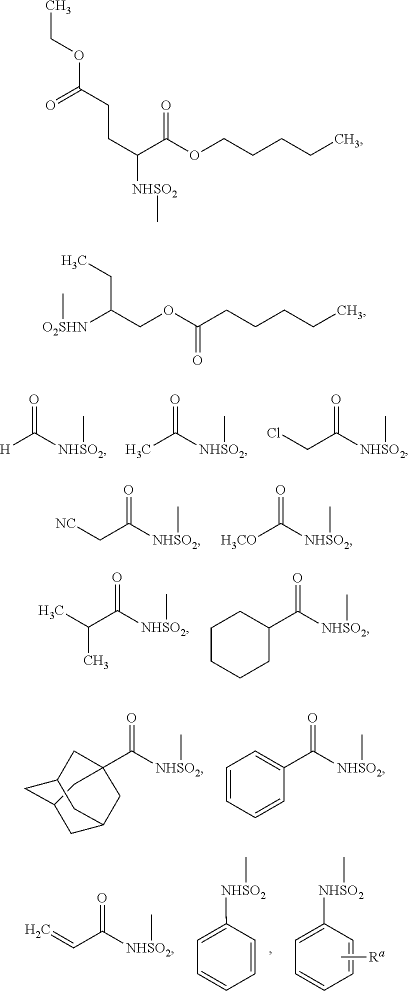

(R^{a} represents a C₁ to C₃ alkyl group or alkoxy group that can be substituted by a halogen atom),

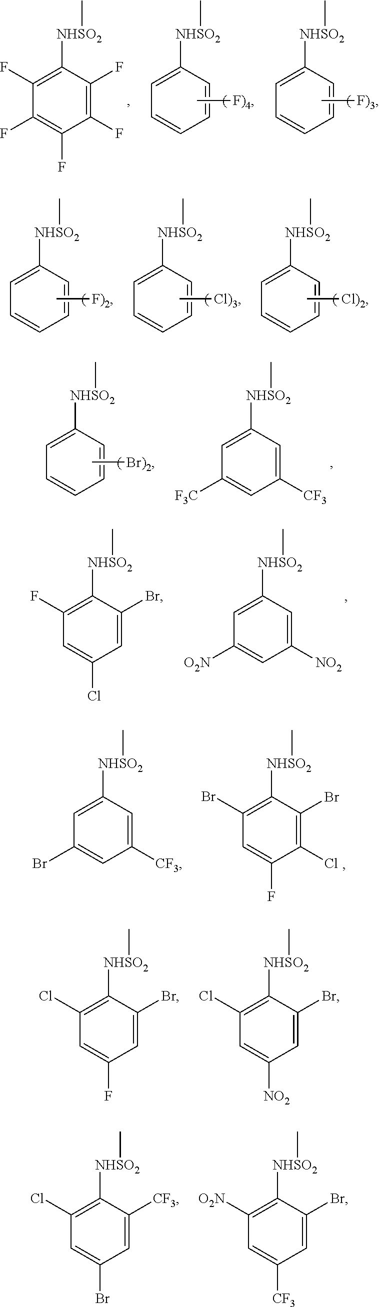

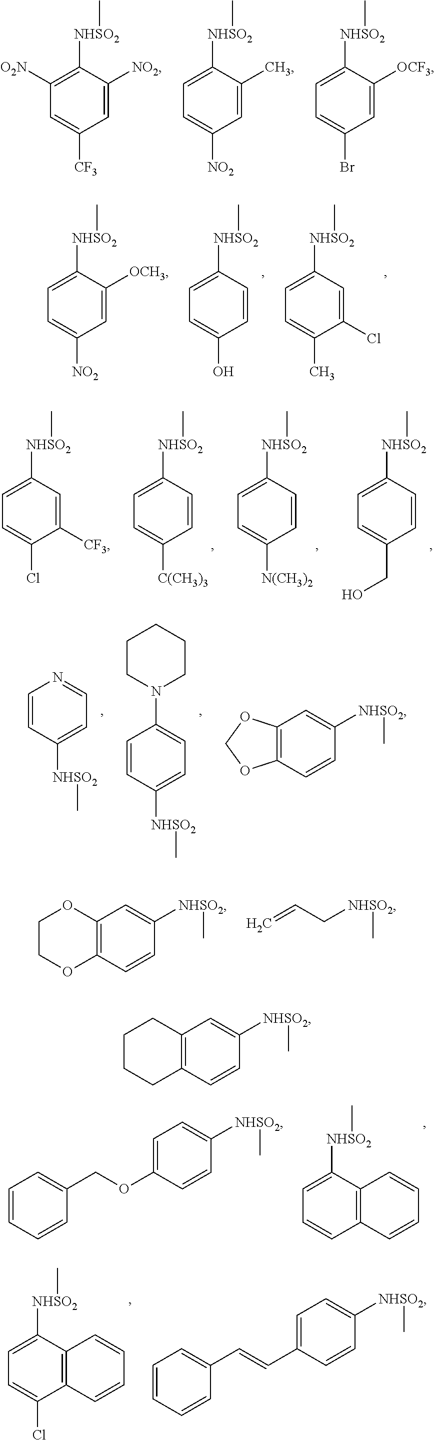

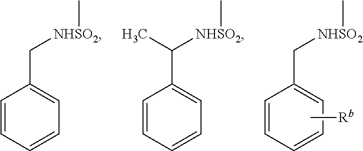

(R^{b} represents a C₁ to C₃ alkyl group or alkoxy group that can be substituted by a halogen atom),

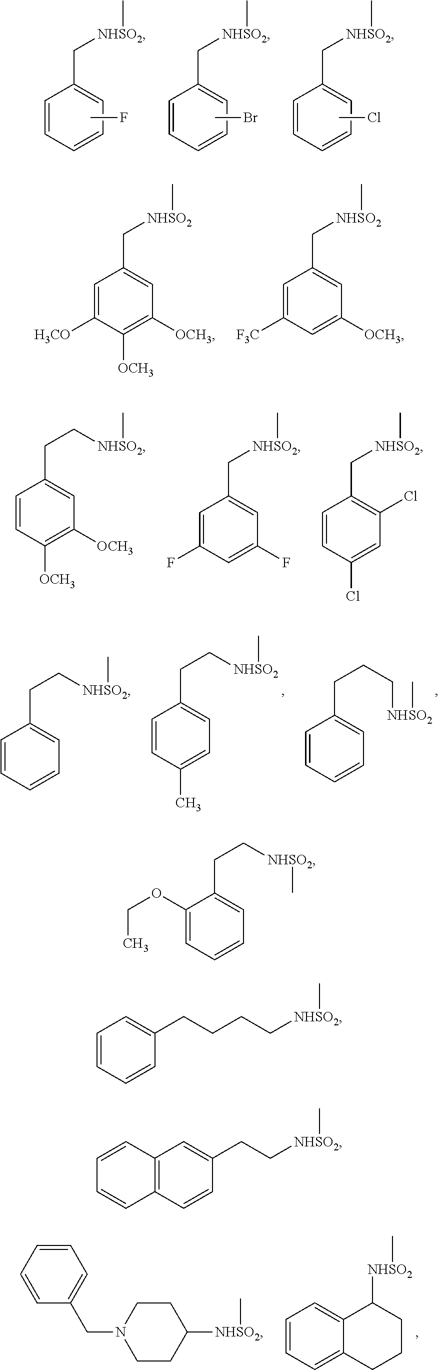

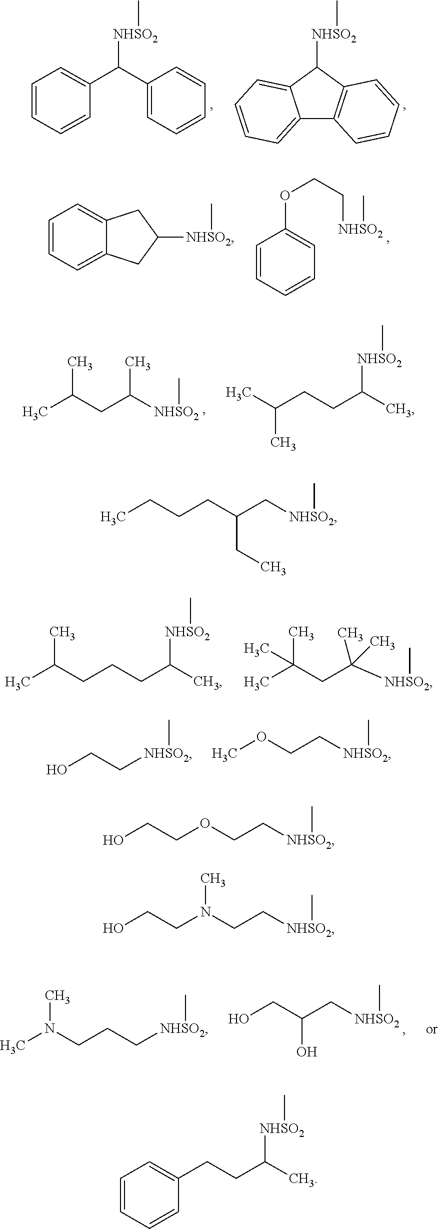

—SO₂NR²⁸R²⁹ preferably includes:

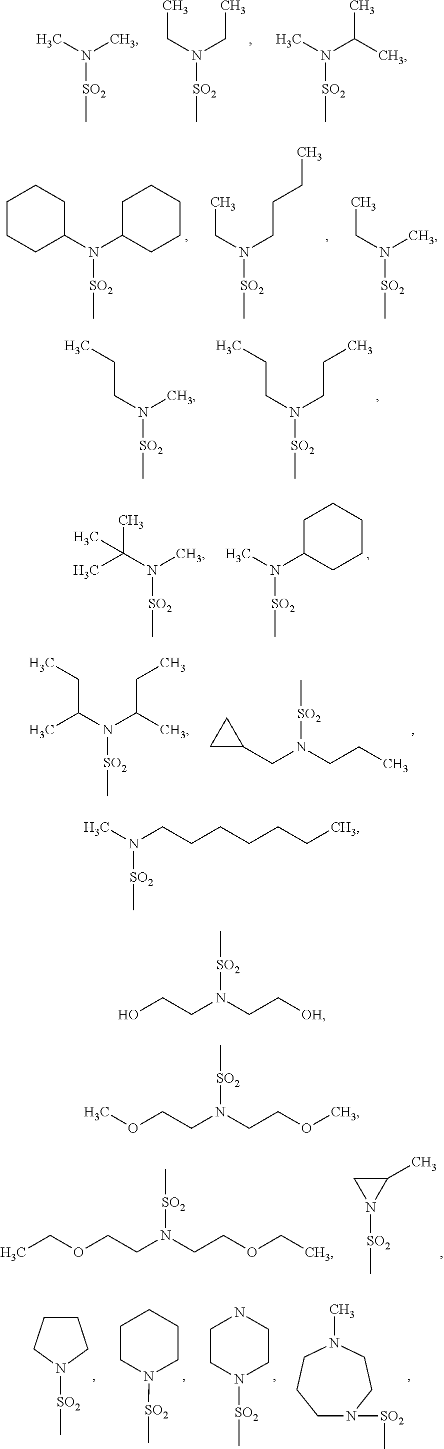

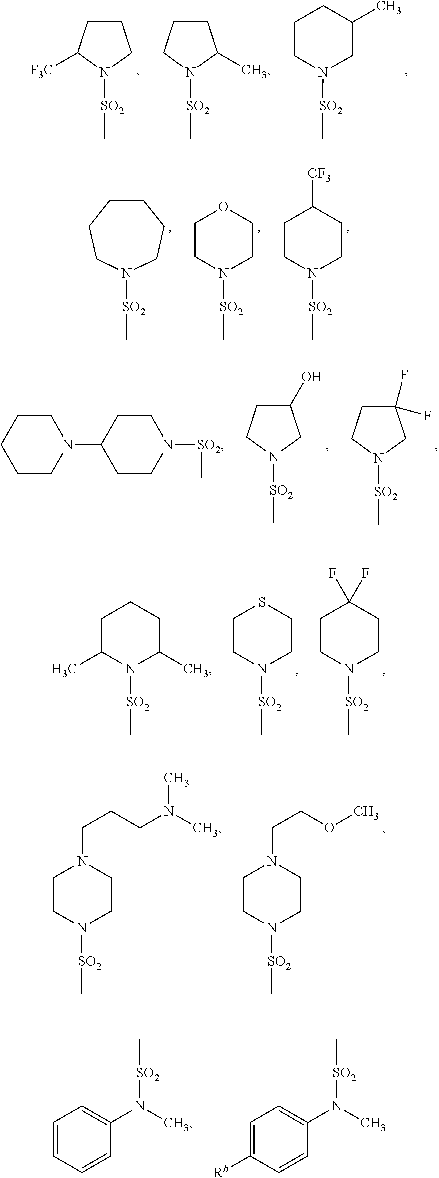

(R^{b} represents a C₁ to C₃ alkyl group or alkoxy group that can be substituted by a halogen atom),

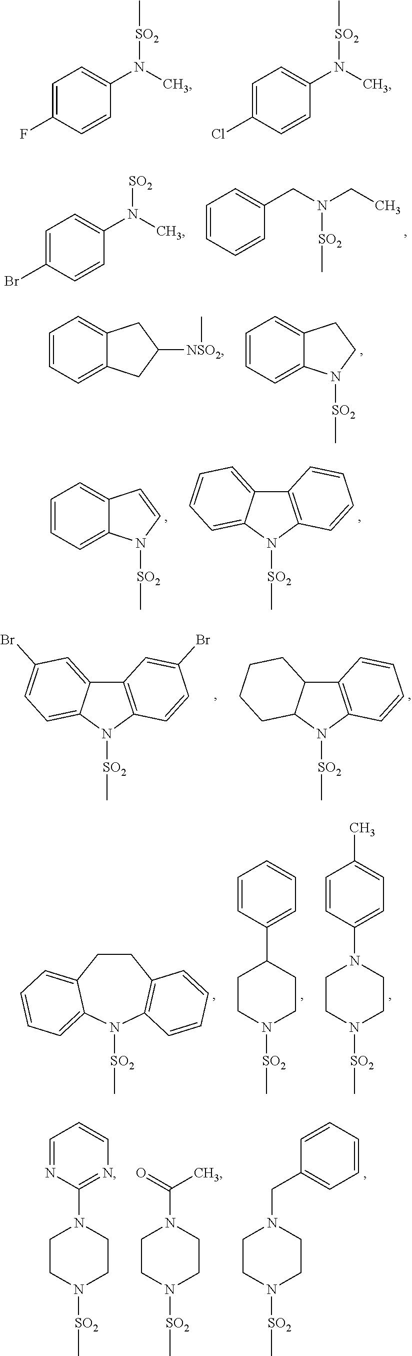

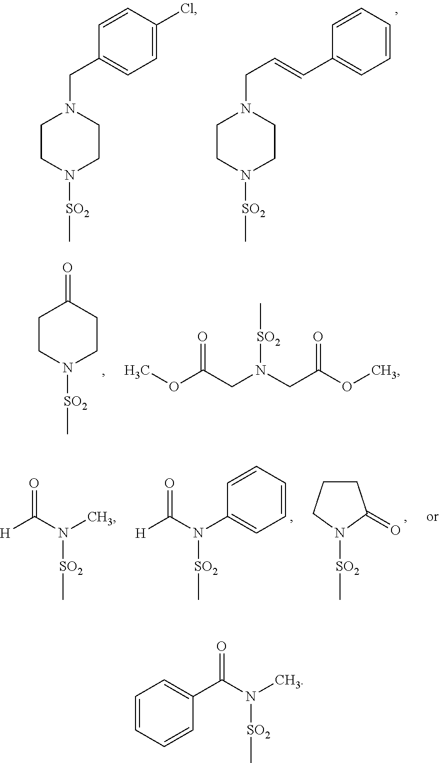

The dye (G) preferably includes at least one red dye selected from the group consisting of red dyes having the structures of formula (16-1) to formula (16-4):

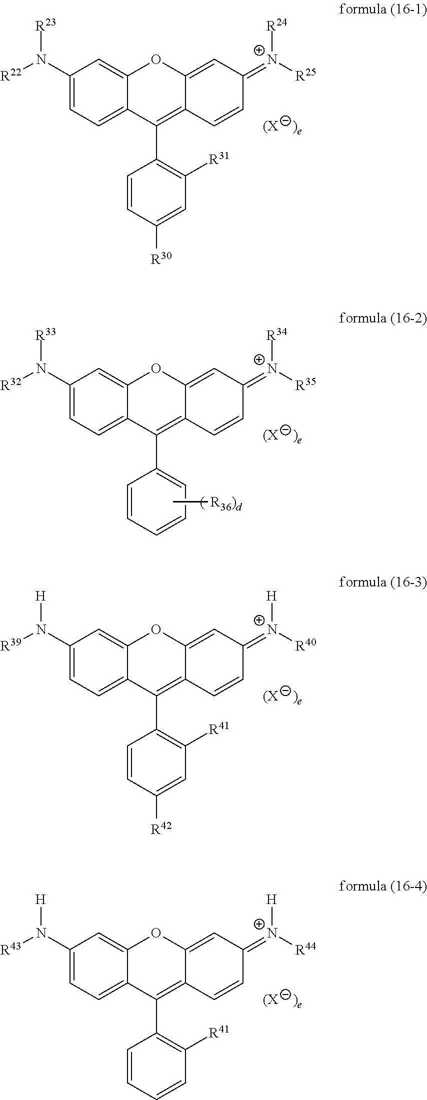

In formula (16-1) to formula (16-4), X represents a halogen atom. e represents 0 or 1.

In formula (16-1), the definitions of R²² to R²⁵ are the same for formula (16). R³⁰ represents hydrogen, —SO₃⁻, —SO₃H, —SO₂NHR²⁸, or —SO₂NR²⁸R²⁹. R³¹ represents —SO₃⁻, —SO₃H, —SO₂NHR ²⁸, or —SO₂NR²⁸R²⁹.

In formula (16-2), R³² to R³⁵ each independently represent hydrogen, —R³⁷, a C₆ to C₁₀ aromatic hydrocarbon group, or a C₆ to C₁₀ aromatic hydrocarbon group substituted by a halogen atom, —R³⁷, —OH, —OR³⁷, —SO₃⁻, —SO₃H, —SO₃Na, —COOH, —COOR³⁷, —SO₃R³⁷, or —SO₂NHR³⁸. R³⁶ each independently represents —SO₃⁻, —SO₃H, —SO₃Na, —COOH, —COOR³⁷, or —SO₂NHR³⁸. d represents an integer of 0 to 5.

R³⁷ represents a C₁ to C₁₀ alkyl group that can be substituted by a halogen atom or —OR³⁹. R³⁸ represents hydrogen, —R³⁷, —COOR³⁷, a C₆ to C₁₀ aromatic hydrocarbon group, or a C₆ to C₁₀ aromatic hydrocarbon group substituted by —R³⁷ or —OR³⁷. R³⁹ represents a C₁ to C₁₀ alkyl group.

In formula (16-3), R³⁹ and R⁴⁰ each independently represent a phenyl group or a phenyl group substituted by a halogen atom, —R³⁷, —OR³⁷, —COOR³⁷, —SO₃R³⁷, or —SO₂NHR^{38.} R⁴¹ represents —SO₃³¹ or —SO₂NHR³⁸. R⁴² represents hydrogen, —SO₃⁻, or —SO₂NHR³⁸.

In formula (16-4), R⁴³ and R⁴⁴ each independently represent a phenyl group or a phenyl group substituted by —R³⁷ or —SO₂NHR³⁸. R⁴¹ represents —SO₃⁻ or —SO₂NHR³⁸.

The dye (G) can include, for instance, the specific examples of the following formula (17) to formula (43):

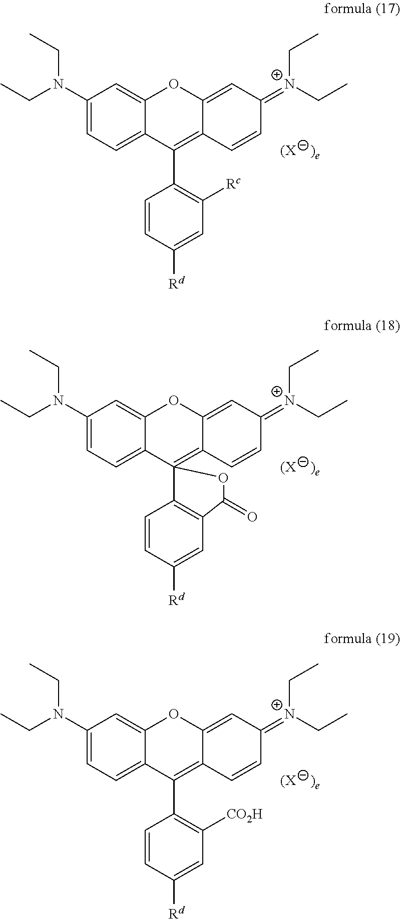

In formula (17) to formula (19), R_{c} and R^{d} each independently represent hydrogen, —SO₃⁻, —COOH, or —SO₂NHR⁴⁵. R⁴⁵ represents 2-ethylhexyl. X represents a halogen atom. e represents 0 or 1.

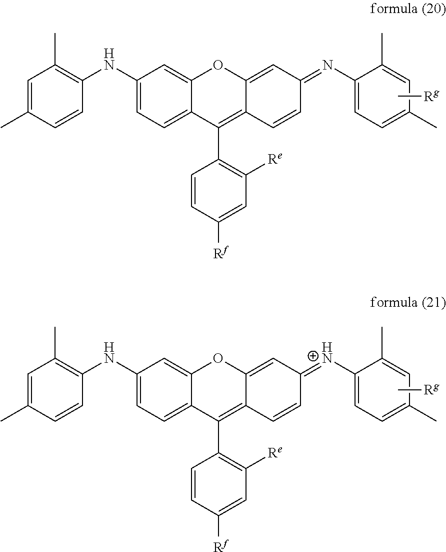

In formula (20) to formula (21), R^{e}, R^{f}, and R^{g} each independently represent —SO₃⁻, —SO₃Na, or —SO₂NHR⁴⁵. R⁴⁵ represents 2-ethylhexyl.

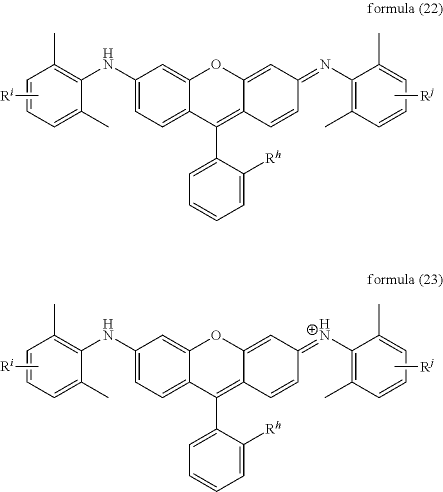

In formula (22) to formula (23), R^{h}, Rⁱ, and R^{j} each independently represent hydrogen, —SO₃⁻, —SO₃Na, or —SO₂NHR⁴⁵. R⁴⁵ represents 2-ethylhexyl.

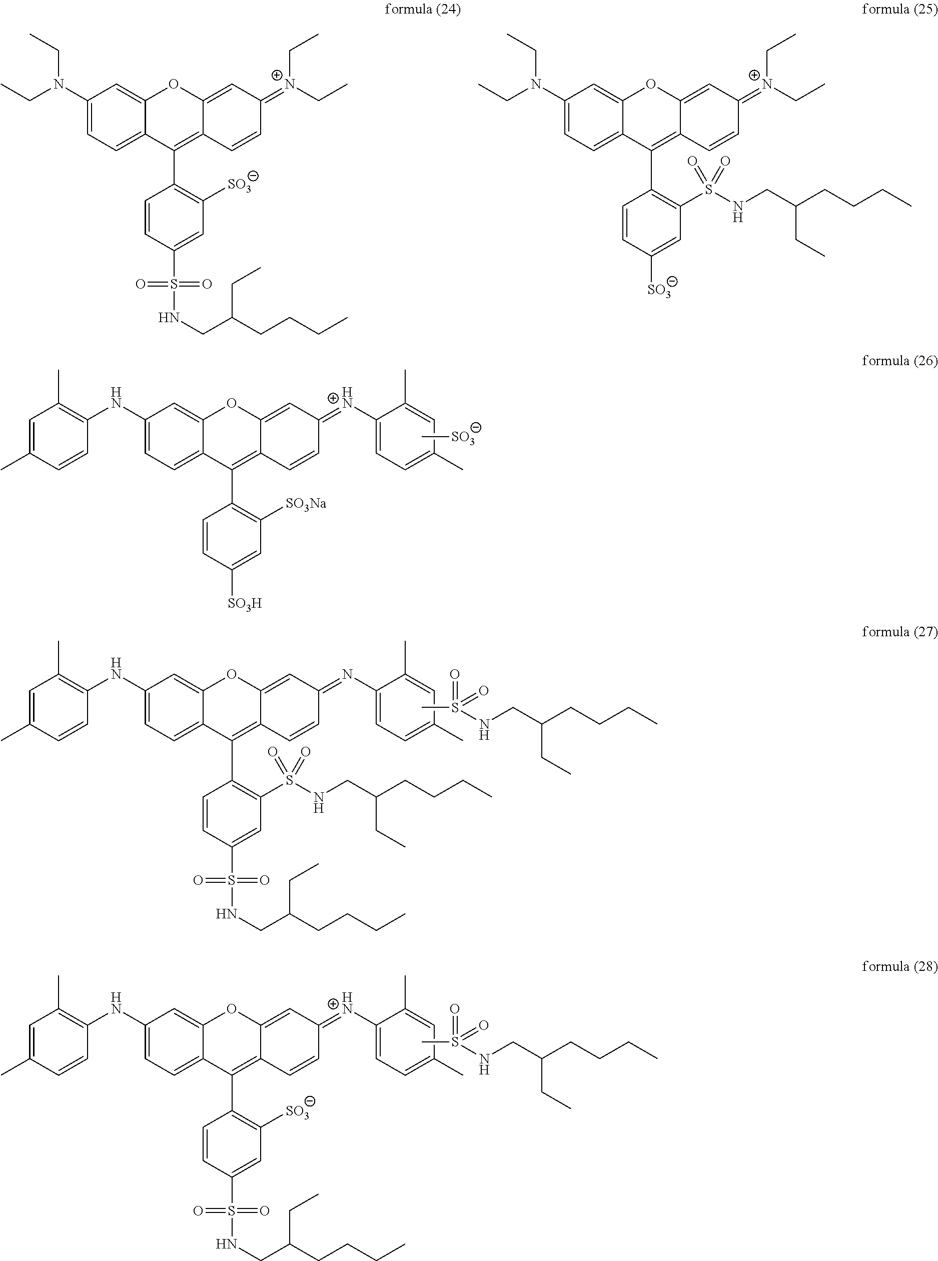

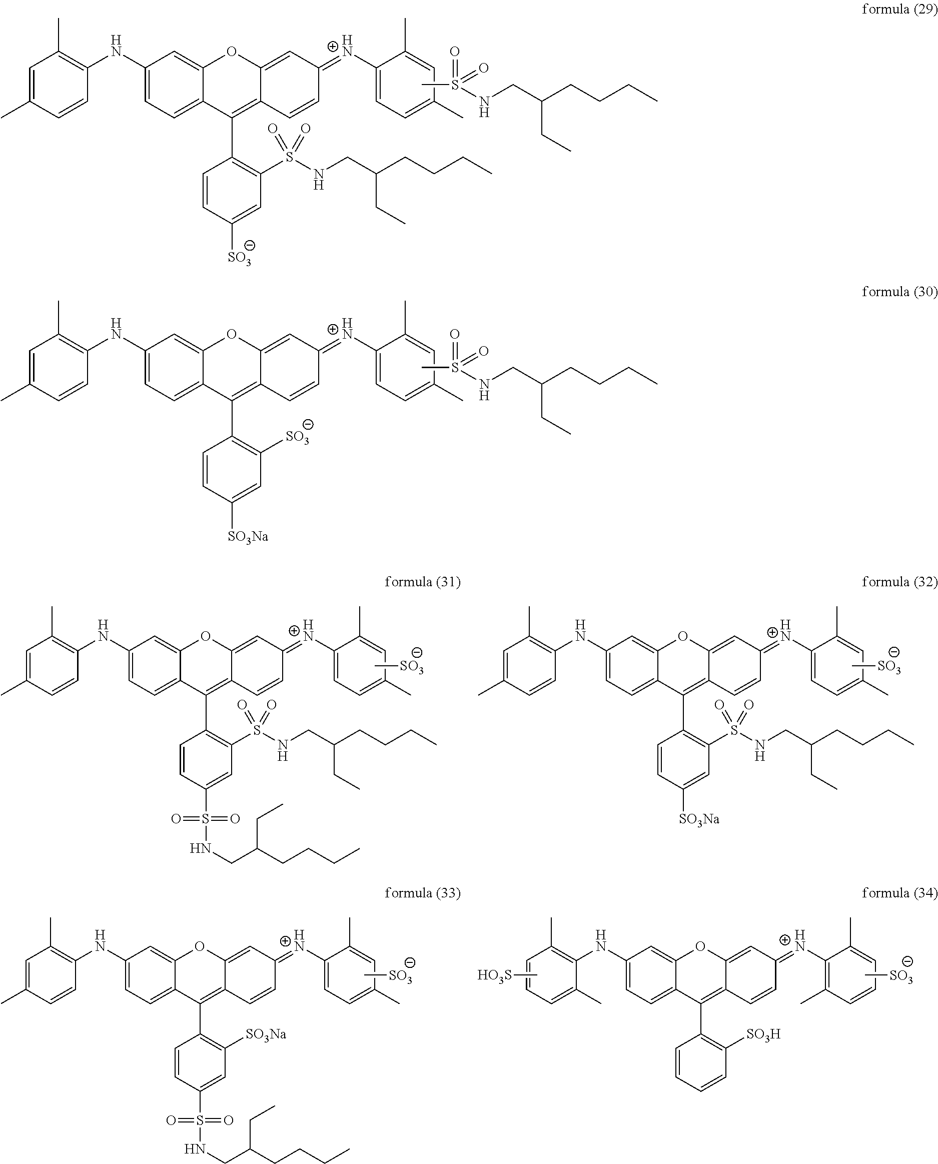

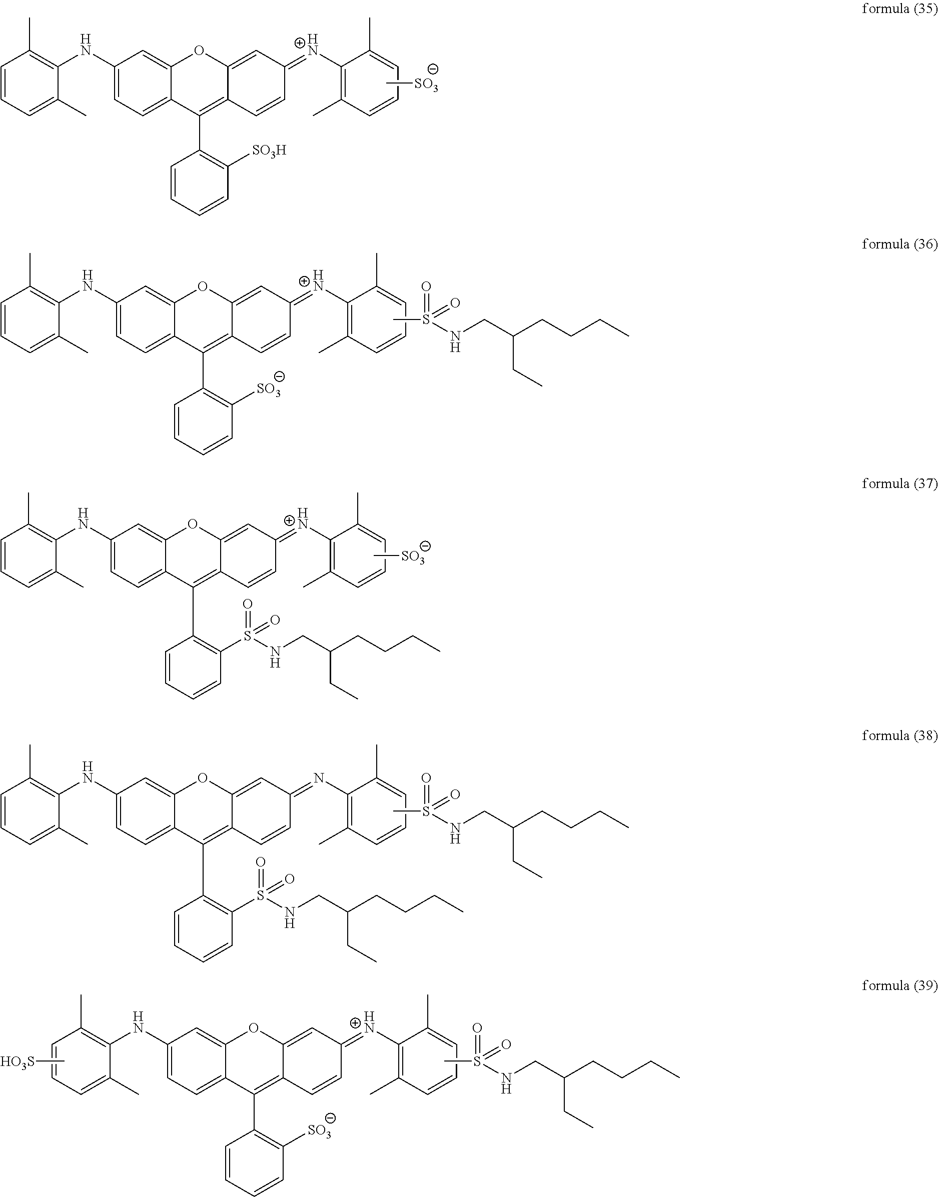

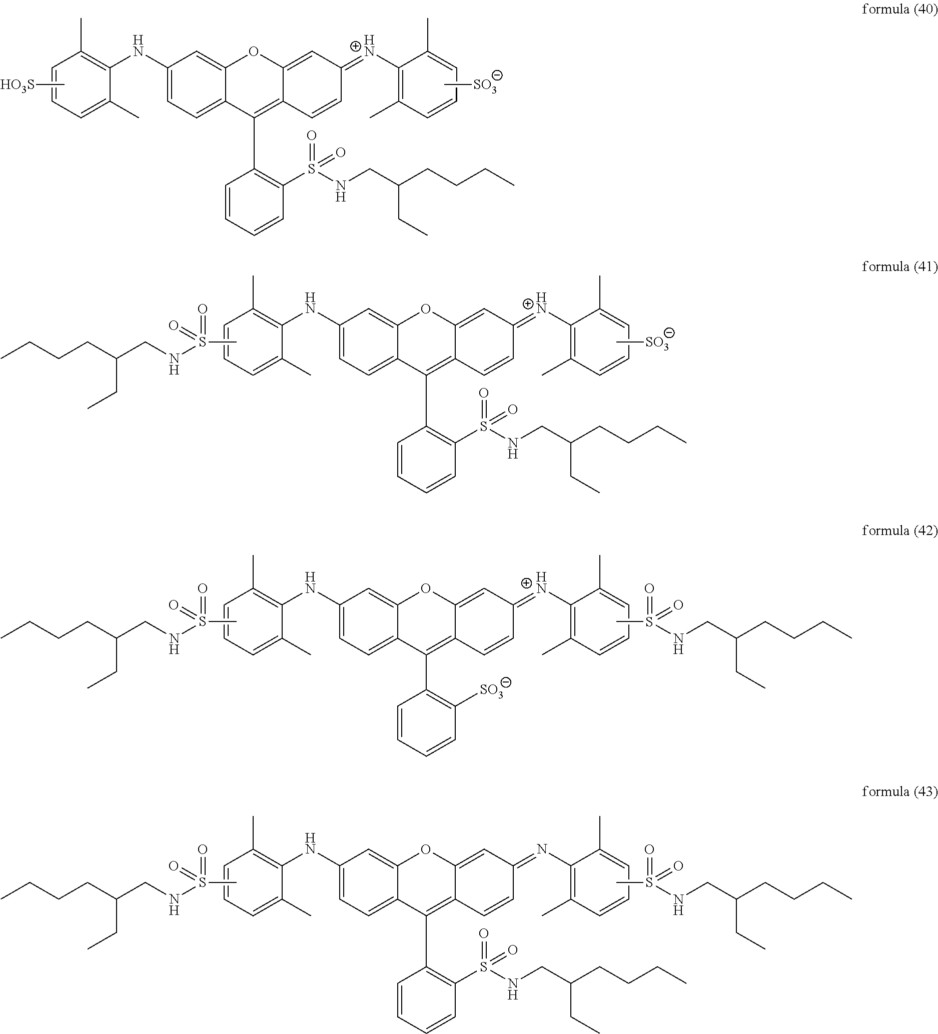

Preferred specific examples of the dye (G) include formula (17) (R^{c} and R^{d} are —SO₃⁻, e is 0) [C.I. Acid Red Dye 52], formula (34) [C.I. Acid Red Dye 289], formula (40), formula (43), or a combination thereof.

In the photosensitive resin composition of the invention, based on 100 parts by weight of the alkali-soluble resin (A), the usage amount of the dye (G) is 3 parts by weight to 30 parts by weight, preferably 4 parts by weight to 25 parts by weight, and more preferably 5 parts by weight to 20 parts by weight.

### Additive (H)

The additive (H) includes, for instance, a surfactant, a filler, a polymer compound (other than the alkali-soluble resin (A)), an adhesion promoting agent, an antioxidant, an ultraviolet absorber, or an anti-coagulant.

The surfactant can improve the coating properties of the photosensitive resin composition of the invention, and examples thereof can include: a polyethylene oxide alkyl ether such as polyethylene oxide lauryl ether, polyethylene oxide stearyl ether, or polyethylene oxide oleyl ether; a polyethylene oxide alkyl phenyl ether such as polyethylene oxide octyl phenyl ether or polyethylene oxide nonyl phenyl ether; a polyethylene glycol dialkyl ester such as polyethylene glycol dilaurate or polyethylene glycol distearate; a sorbitan fatty acid ester; a fatty acid modified polyester; a tertiary amine modified polyurethane; and a KP product manufactured by Shin-Etsu Chemical Co., Ltd., an SF-8427 product manufactured by Toray Dow Corning, a Polyflow product manufactured by Kyoei-Sha Yushi Kagaku Kogyo Co., Ltd., an F-Top product manufactured by Tochem Products Co., Ltd., a Megafac product manufactured by Dainippon Ink & Chemicals, Inc., a Fluorade product manufactured by Sumitomo 3M Co., Ltd., an Asahi Guard product manufactured by Asahi Glass Co., Ltd., and a Surflon product manufactured by Asahi Glass Co., Ltd.

The additive can include, for instance: glass or aluminum. The polymer compound can include, for instance: polyvinyl alcohol, polyethylene glycol monoalkyl ether, or polyfluoro alkyl acrylate. The adhesion promoting agent can include, for instance: vinyltrimethoxysilane, vinyltriethoxysilane, vinyltris(2-methoxyethoxy)silane, N-(2-aminoethyl)-3-aminopropyl methyldimethoxysilane, N-(2-aminoethyl)-3-aminopropyltrimethoxysilane, 3-aminopropyl triethoxysilane, 3-glycidyloxy propyltrimethoxysilane, 3-glycidyloxypropylmethyl dimethoxysilane, 2-(3,4-epoxycyclohexyl)ethyltrimethoxysilane, 3-chloropropylmethyl dimethoxysilane, 3-chloropropyltrimethoxysilane, 3-methacryloyloxypropyltrimethoxysilane, or 3-mercaptopropyltrimethoxysilane.

The antioxidant can include, for instance: 2,2-thiobis(4-methyl-6-t-butylphenol) or 2,6-di-t-butylphenol. The ultraviolet absorber can include, for instance: 2-(3-t-butyl-5-methyl-2-hydroxyphenyl)-5-chlorophenylazide or alkoxyphenone. The anti-coagulant can include, for instance: sodium polyacrylate.

### Preparation Method of Photosensitive Resin Composition

A preparation method of the photosensitive resin composition can include, for instance: placing and stirring the alkali-soluble resin (A), the compound (B) containing an ethylenically unsaturated group, the photoinitiator (C), the organic solvent (D), and the compound (E) represented by formula (1) in a stirrer such that the components are uniformly mixed into solution state. The additive (H) can also be added as needed. After the components are uniformly mixed, a transparent photosensitive resin composition in solution state can be obtained. The pigment (F) and the dye (G) can be added in the preparation process of the photosensitive resin composition as needed. After the components are uniformly mixed, a color photosensitive resin composition in solution state can be obtained. The color photosensitive resin composition in liquid state can be used in the forming of the subsequent pixel layer, protective film, or spacer.

In addition, the preparation method of the photosensitive resin composition is not particularly limited. The preparation method of the photosensitive resin composition includes, for instance, first dispersing a portion of the alkali-soluble resin (A) and the compound (B) containing an ethylenically unsaturated group in a portion of the organic solvent (D) to form a dispersion solution, and then mixing the rest of the alkali-soluble resin (A), the compound (B) containing an ethylenically unsaturated group, the photoinitiator (C), the organic solvent (D), the compound (E) represented by formula (1), the pigment (F), and the dye (G).

Alternatively, the photosensitive resin composition can also be prepared by first dispersing a portion of the compound (E) represented by formula (1) in a portion of the organic solvent (D) to form a dispersion, and then mixing the rest, and then mixing the remaining alkali-soluble resin (A), compound (B) containing an ethylenically unsaturated group, the photoinitiator (C), the organic solvent (D), the compound (E) represented by formula (1), the pigment (F), and the dye (G).

### Pixel Layer, Protective Film, and Spacer

The invention provides a pixel layer, a protective film, and a spacer formed by the above photosensitive resin composition. The preparation method thereof is described in detail below.

### Forming of Pixel Layer

The forming method of the pixel layer of the invention includes coating the color photosensitive resin composition on a substrate, and then performing a heat treatment such as baking to remove the solvent therein, so as to form a color pixel layer.

The photosensitive resin composition of the invention in solution state is coated on the substrate via a coating method such as spin coating, cast coating, or roll coating. The substrate can include: a glass for a liquid crystal display apparatus such as alkali-free glass, soda-lime glass, hard glass (Pyrex glass), quartz glass, or a glass attached with a transparent conductive film; a substrate (such as a silicon substrate) for a photoelectric conversion apparatus (such as a solid-state imaging device); or a substrate having a pre-formed light-shielding black matrix capable of isolating, for instance, red, green, and blue pixel color layers.

After coating, most of the organic solvent in the photosensitive resin composition is first removed by a method of drying under reduced pressure. Next, the remaining organic solvent is completely removed by a pre-bake method to form a pre-baked coating film. During the process, the operating conditions of the drying process under reduced pressure and the pre-bake process vary with the type and the mix ratio of each component. Generally, the drying process under reduced pressure is performed at a pressure of 0 mmHg to 200 mmHg for 1 second to 60 seconds, and the pre-bake process is performed at a temperature of 70° C. to 100° C. for 1 minute to 15 minutes.

After pre-bake, an exposure process is performed on the pre-baked coating film using a photomask with a predetermined pattern. The light used in the exposure process is preferably an ultraviolet (UV) ray such as a g-ray, an h-ray, or an i-ray, and the equipment for emitting the UV ray is, for instance, a(n) (ultra-)high pressure mercury lamp or a metal halide lamp.

After the exposure process, the pre-baked coating film is immersed in a developing solution at a temperature of 23±2° C. and developed for about 15 seconds to 5 minutes to remove the unnecessary portion of the pre-baked coating film so as to form a predetermined pattern on the substrate. The developing solution can be an alkali aqueous solution containing an alkali compound such as sodium hydroxide, potassium hydroxide, sodium carbonate, sodium bicarbonate, potassium carbonate, potassium bicarbonate, sodium silicate, sodium methylsilicate, aqueous ammonia, ethylamine, diethylamine, dimethylethanolamine, tetramethylammonium hydroxide, tetraethyl ammonium hydroxide, choline, pyrrole, piperidine, or 1,8-diazabicyclo-[5,4,0]-7-undecene. The concentration thereof is 0.001 wt % to 10 wt %, preferably 0.005 wt % to 5 wt %, and more preferably 0.01 wt % to 1 wt %.

Then, the pattern on the substrate is cleaned with water, and then the pattern is air-dried with compressed air or compressed nitrogen. Lastly, a post-bake process is performed on the pattern with a heating apparatus such as a hot plate or an oven. The heating temperature is set between 150° C. and 250° C., the heating time when using the hot plate is 5 minutes to 60 minutes, and the heating time when using the oven is 15 minutes to 150 minutes. The pattern is thus fixed to form the pixel layer. By repeating the steps, pixel layers of, for instance, red, green, and blue can be formed in sequence on the substrate.

### Forming of Protective Film and Spacer

The forming method of the protective film of the invention includes first forming a pixel layer composed of a red, a green, and a blue color layer on a transparent substrate, and then coating the transparent photosensitive resin composition on the substrate on which, for instance, red, green, and blue pixel color layers are formed. Then, steps such as exposure, development, and post-bake are performed to remove the solvent therein, so as to form a color filter layer protective film.

The forming method of the spacer of the invention includes first forming a transparent conductive film on a transparent substrate on which a protective film and a pixel layer are formed, and then coating the transparent photosensitive resin composition on the transparent conductive film. Then, steps such as exposure, development, and post-bake are performed to remove the solvent therein, so as to form the spacer.

In other words, if the protective film is to be formed, the photosensitive resin composition is coated on the pixel layer on the substrate; and if the spacer is to be formed, the photosensitive resin composition is coated on the transparent conductive film on the substrate.

The coating method can be, for instance, spray coating, roller coating, spin coating, bar coating, or ink jet coating. The coating method is preferably performed with a spin coater, a spin-less coating machine, or a slit-die coating machine.

Conditions of the pre-bake vary with the type and the mix ratio of each component. In general, the pre-bake is performed at a temperature of 70° C. to 90° C. for 1 minute to 15 minutes. After the pre-bake, the thickness of the pre-baked coating film is 0.15 μm to 8.5 μm, preferably 0.15 μm to 6.5 μm, and more preferably 0.15 μm to 4.5 μm. It should be understood that the thickness of the pre-baked coating film refers to the thickness after the solvent is removed.

After the pre-baked coating film is formed, a heat treatment is performed with a heating apparatus such as a hot plate or an oven. The temperature of the heat treatment is generally 150° C. to 250° C., wherein the heating time when using the hot plate is 5 minutes to 30 minutes, and the heating time when using the oven is 30 minutes to 90 minutes.

When the curable resin composition contains the photoinitiator, if needed, an exposure treatment is performed on the pre-baked coating film after the curable resin composition is coated on the surface of the substrate and the solvent is removed with a pre-bake method to form the pre-baked coating film.

The light used for the exposure treatment can be, for instance, visible light, UV ray, far-UV ray, electron beam, or x-ray. However, light containing UV ray and having a wavelength of 190 nm to 450 nm is preferred.

The amount of exposure of the exposure treatment is preferably 100 J/m² to 20,000 J/m², but more preferably 150 J/m² to 10,000 J/m².

After the exposure treatment, a heat treatment can optionally be performed with a heating apparatus such as a hot plate or an oven. The temperature of the heat treatment is generally 150° C. to 250° C., wherein the heating time when using the hot plate is 5 minutes to 30 minutes, and the heating time when using the oven is 30 minutes to 90 minutes.

The protective film and the spacer of the invention are not limited to be formed on the pixel layer or the transparent conductive film, and can be formed on the substrate or various elements on the substrate.

### Manufacturing Method of Thin-Film Transistor and Color Filter

The invention provides a thin-film transistor containing the above protective film. The invention also provides a color filter containing the above spacer, pixel layer, or protective film. The preparation method thereof is described in detail below.

### Thin-Film Transistor

Specifically, the manufacturing method of the thin-film transistor of the invention includes, for instance: coating the photosensitive resin composition of the invention on a glass substrate or plastic substrate containing, for instance, an aluminum, chromium, silicon nitride, or noncrystalline silicon thin film via a method such as spin coating, cast coating, or roll coating, thus forming a photoresist layer. Then, steps such as pre-bake, exposure, development, and post-bake treatments are performed to form a photosensitive resin pattern. Then, steps of etching and photoresist peeling are performed to obtain a thin-film transistor (TFT) containing a cured product formed by curing the photosensitive resin composition of the invention.

### Color Filter

Specifically, the manufacturing method of the color filter of the invention includes, for instance: after red, green, and blue pixel color layers and the protective film are formed, sputtering is performed on the surface of the protective film layer under a vacuum environment at a temperature between 220° C. and 250° C. to form an ITO protective film. If needed, etching is performed on the ITO protective film, and wiring is performed, and then an alignment film is coated on the ITO protective film surface, so as to manufacture a color filter containing a cured product formed by curing the photosensitive resin composition of the invention.

### Manufacturing Method of Liquid Crystal Display Apparatus

The invention provides a liquid crystal display apparatus containing the above thin-film transistor or color filter. The manufacturing method thereof is described in detail below.

First, the color filter formed by the forming method of a color filter and a substrate provided with a thin-film transistor formed by the forming method of a thin-film transistor are disposed opposite to each other, and a gap (cell gap) is left between the two. Then, the color filter and the peripheral portion of the substrate are adhered with an adhesive and an injection hole is left. Then, a liquid crystal is injected into the gap separated by the substrate surface and the adhesive through the injection hole, and then the injection hole is sealed to form a liquid crystal layer. Then, a polarizer is provided to each of the other side of the color filter in contact with the liquid crystal layer and the other side of the substrate in contact with the liquid crystal layer to form a liquid crystal display device. Next, a surface light source is disposed on one side of the liquid crystal display device to form a liquid crystal display apparatus. The liquid crystal used, i.e., a liquid crystal compound or a liquid crystal composition, is not particularly limited., and any liquid crystal compound or liquid crystal composition can be used.

Moreover, the liquid crystal alignment film used in the fabrication of the color filter is used to limit the alignment of the liquid crystal molecules and is not particularly limited. Both inorganic matter and organic matter can be used, and the invention is not limited thereto.

Embodiments are provided as examples to describe the invention in detail, but the invention is not limited to the contents disclosed in the embodiments.

### EXAMPLES

### Synthesis Examples of First Alkai-Soluble Resin (A-1)

In the following, synthesis example A-1-1 to synthesis example A-1-3 of the first alkali-soluble resin (A-1) are described:

### Synthesis Example 1

### Manufacturing Method of First Alkali-Soluble Resin (A-1-1) Having an Unsaturated Group

100 parts by weight of a fluorene epoxy compound (ESF-300 manufactured by Nippon Steel Chemical; epoxy equivalent: 231), 30 parts by weight of acrylic acid, 0.3 parts by weight of benzyltriethylammonium chloride, 0.1 parts by weight of 2,6-di-t-butyl-p-cresol, and 130 parts by weight of propylene glycol monomethyl ether acetate were added continuously to a 500 mL 4-neck flask. The feed rate was controlled at 25 parts by weight/minute. The temperature of the reaction process was maintained at 100° C. to 110° C. and the reaction lasted 15 hours. A light yellow transparent mixture (A-1-1′) having a solid content concentration of 50 wt % was thus obtained.

Then, 100 parts by weight of the light yellow transparent mixture (A-1-1′) was dissolved in 25 parts by weight of glycol ether acetate, and 6 parts by weight of tetrahydrophthalic anhydride and 13 parts by weight of benzophenone tetracarboxylic dianhydride were added at the same time, and the mixture was heated to 110° C. to 115° C. and reacted for 2 hours, thus obtaining a resin having an unsaturated group (hereinafter A-1-1) having an acid value of 98.0 mgKOH/g.

### Synthesis Example 2

### Manufacturing Method of First Alkali-Soluble Resin (A-1-2) Having an Unsaturated Group

100 parts by weight of the light yellow transparent mixture (A-1-1′) obtained in synthesis example 1 was dissolved in 25 parts by weight of glycol ether acetate, and 13 parts by weight of benzophenone tetracarboxylic dianhydride was added. The mixture was reacted at 90° C. to 95° C. for 2 hours, and then 6 parts by weight of tetrahydrophthalic anhydride was added, and the mixture was reacted at 90° C. to 95° C. for 4 hours, thus obtaining a resin having an unsaturated group (hereinafter A-1-2) having an acid value of 99.0 mgKOH/g.

### Synthesis Example 3

### Manufacturing Method of First Alkali-Soluble Resin (A-1-3) Having an Unsaturated Group

400 parts by weight of an epoxy compound [model: NC-3000, made by Nippon Kayaku; epoxy equivalent: 288], 102 parts by weight of acrylic acid, 0.3 parts by weight of p-methoxyphenol, 5 parts by weight of triphenylphosphine, and 264 parts by weight of propylene glycol monomethyl ether acetate were placed in a reaction flask, the temperature of the reaction process was maintained at 95 , and reaction was performed for 9 hours to obtain an intermediate product having an acid value of 2.2 mgKOH/g. Then, 151 parts by weight of tetrahydrophthalic anhydride was added, and reaction was performed at 95° C. for 4 hours to obtain a resin having an unsaturated group (hereinafter A-1-3) and having an acid value of 102 mgKOH/g and a weight-average molecular weight of 3,200.

### Synthesis Examples of Second Alkai-Soluble Resin (A-2)

In the following, synthesis example A-2-1 to synthesis example A-2-3 of the second alkali-soluble resin (A-2) are described:

### Synthesis Example 4

### Manufacturing Method of Second Alkali-Soluble Resin (A-2-1)

1 part by weight of 2,2′-azobisisobutyronitrile, 240 parts by weight of propylene glycol monomethyl ether acetate, 20 parts by weight of methacrylate, 15 parts by weight of styrene, 35 parts by weight of benzyl methacrylate, 10 parts by weight of glycerol monomethacrylate, and 20 parts by weight of N-phenylmaleimide were placed in a round-bottomed flask provided with a stirrer and a condenser, and the flask was filled with nitrogen. Then, stirring was performed slowly and the temperature was increased to 80° C., such that each reactant was uniformly mixed and polymerization reaction was performed for 4 hours. Then, the mixture was heated to 100° C., and 0.5 parts by weight of 2,2′-azobisisobutyronitrile was added to perform polymerization for 1 hour to obtain one other alkali-soluble resin (hereinafter A-2-1).

### Synthesis Example 5

### Manufacturing Method of Second Alkali-Soluble Resin (A-2-2)

2 parts by weight of 2,2′-azobisisobutyronitrile, 300 parts by weight of dipropylene glycol methyl ether, 15 parts by weight of methacrylate, 15 parts by weight of 2-hydroxyethylacrylate, and 70 parts by weight of benzyl methacrylate were placed in a round-bottomed flask provided with a stirrer and a condenser, and the flask was filled with nitrogen. Then, stirring was performed slowly and the temperature was increased to 80° C., such that each reactant was uniformly mixed and a polymerization reaction was performed for 3 hours. Then, the mixture was heated to 100° C., and 0.5 parts by weight of 2,2′-azobisisobutyronitrile was added to perform polymerization for 1 hour to obtain one other alkali-soluble resin (hereinafter A-2-2).

### Synthesis Example 6

### Manufacturing Method of Second Alkali-Soluble Resin (A-2-3)

2 parts by weight of 2,2′-azobisisobutyronitrile, 300 parts by weight of dipropylene glycol methyl ether, 20 parts by weight of 2-methacryloyloxyethyl succinate monoester, 15 parts by weight of dicyclopentenyloxyethyl acrylate, and 65 parts by weight of benzyl methacrylate were placed in a round-bottomed flask provided with a stirrer and a condenser, and the flask was filled nitrogen. Then, stirring was performed slowly and the temperature was increased to 80° C., such that each reactant was uniformly mixed and a polymerization reaction was performed for 3 hours. Then, the mixture was heated to 100° C., and 0.5 parts by weight of 2,2′-azobisisobutyronitrile was added to perform polymerization for 1 hour to obtain one other alkali-soluble resin (hereinafter A-2-3).

### Examples of Photosensitive Resin Composition

Example 1 to example 10 and comparative example 1 to comparative example 5 of the photosensitive resin composition are described below:

### Example 1

100 parts by weight of the second alkali-soluble resin A-2-1 (hereinafter A-2-1), 10 parts by weight of the compound represented by formula (7) (hereinafter B-1-1), 50 parts by weight of the caprolactone-modified dipentaerythritol hexaacrylate (hereinafter B-2-1), 20 parts by weight of 2-methyl-1-(4-methylthiophenyl)-2-morpholino-1-propanone (hereinafter C-1), and 1 part by weight of the compound represented by formula (1) (wherein R′ represents a methyl group, m=0) (hereinafter E-1) were added to 500 parts by weight of propylene glycol monomethyl ether acetate (hereinafter D-1), and the mixture was uniformly stirred via a shaking-type stirrer to obtain the photosensitive resin composition of example 1. The obtained photosensitive resin composition was evaluated by each of the following evaluation methods, and the results are as shown in Table 2.

### Example 2 to Example 10

The photosensitive resin compositions of example 2 to example 10 were prepared using the same steps as example 1, and the difference thereof is: the type and the usage amount of the components of the photosensitive resin compositions were changed (as shown in Table 2). The obtained photosensitive resin composition was evaluated by each of the following evaluation methods, and the results are as shown in Table 2.

### Comparative Example 1 to Comparative Example 5

The photosensitive resin compositions of comparative example 1 to comparative example 5 were prepared using the same steps as example 1, and the difference thereof is: the type and the usage amount of the components of the photosensitive resin compositions were changed (as shown in Table 3). The obtained photosensitive resin composition was evaluated by each of the following evaluation methods, and the results are as shown in Table 3.

The compounds corresponding to the abbreviations in Table 2 and Table 3 are as shown below.

| Abbre- | |
|---|---|
| viation | Compound |
| A-1-1 | First alkali-soluble resin (A-1-1) having an unsaturated group |
| | of synthesis example 1 |
| A-1-2 | First alkali-soluble resin (A-1-2) having an unsaturated group |
| | of synthesis example 2 |
| A-1-3 | First alkali-soluble resin (A-1-3) having an unsaturated group |
| | of synthesis example 3 |
| A-2-1 | Other alkali-soluble resins (A-2-1) of synthesis example 4 |
| A-2-2 | Other alkali-soluble resins (A-2-2) of synthesis example 5 |
| A-2-3 | Other alkali-soluble resins (A-2-3) of synthesis example 6 |
| B-1-1 | Compound shown in formula (7) p = 12 |
| B-1-2 | Compound shown in formula (8) q = 6 |
| B-1-3 | Compound shown in formula (9) |
| B-1-4 | Compound shown in formula (10) |
| B-2-1 | Caprolactone-modified dipentaerythritol hexaacrylate |
| B-2-2 | Dipentaerythritol hexaacrylate |
| B-2-3 | Pentaerythritol tetraacrylate |
| C-1 | 2-methyl-1-(4-methylthiophenyl)-2-morpholino-1-acetone |
| C-2 | 2,2′-bis(2,4-dichlorophenyl)-4,4′,5,5′-tetraphenylbiimidazole |
| C-3 | 1-[4-(phenylthio)phenyl]octane-1,2-dione 2-(O-benzoyl-oxime) |
| C-4 | 4,4′-bis(diethylamino)benzophenone |
| D-1 | Propylene glycol methyl ether acetate |
| D-2 | Ethyl 3-ethoxypropionate |
| E-1 | Compound shown in formula (1), R′₁ = CH₃, R′₂ = CH₃, m = 0 |
| E-2 | Compound shown in formula (1), R′₁ = H, R′₂ = H, m = 1, |
| | R″ = CH₃ |
| E-3 | Compound shown in formula (1), R′₁ = CH₂ C₆H₅, R′₂ = CH₂ |
| | C₆H₅, m = 2, R″ = CH₃ |
| E-4 | Compound shown in formula (1), R′₁ = H, R′₂ = H, m = 2, |
| | R″ = n-C₄H₉ |
| E-5 | Compound shown in formula (1), R₁′ = H, R′₂ = H, m = 0 |
| e-1 | “NIKALAC” MX-270 |
| e-2 | 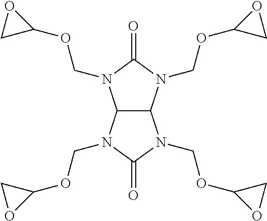 [SMILES: O=C1N(COC2CO2)C2C(N1COC1CO1)N(COC1CO1)C(=O)N2COC1CO1] |
| F-1 | C.I. Pigment R254/C.I. Pigment Y139 = 80/20 |
| F-2 | C.I. Pigment G36/C.I. Pigment Y150 = 60/40 |
| F-3 | C.I. Pigment B15:6 |
| G-1 | Compound shown in formula (17), R^{c}, R^{d} = —SO₃⁻, e = 0 |
| G-2 | Compound shown in formula (34) |
| G-3 | C.I. Acid Red 37 |
| G-4 | Disperse Red 60 |
| H-1 | 2,2-thiobis(4-methyl-6-t-butylphenol) |
| H-2 | 2-(3-t-butyl-5-methyl-2-hydroxyphenyl)-5-chlorophenylazide |

### Evaluation Methods

### (a) Development Properties

The photosensitive resin composition was coated on a 100 mm×100 mm glass substrate by a spin coating method, and was first dried under reduced pressure at a pressure of 100 mmHg and a time of 30 seconds, and then pre-baked at a temperature of 80° C. and a time of 3 minutes to form a pre-baked coating film having a film thickness of 2.5 μm.

Then, 2 ml of a 2 wt % aqueous solution of potassium hydroxide was added dropwise on the pre-baked coating film, the time t needed for the pre-baked coating film to dissolve was measured, which is equivalent to the development time, and evaluation was performed according to the following criteria:
⊚: t≦15 seconds;
◯: 15 seconds<t≦20 seconds;
Δ: 20 seconds<t ≦25 seconds;
×: 25 seconds<t.

### (b) High-Precision Pattern Linearity

300 mJ/cm² of UV (exposure machine: Canon PLA-501F) was irradiated on the pre-baked coating film after the development evaluation to perform exposure via a stripe-pattern photomask having a width of 25 μm (pitch: 50 μm), then the pre-baked coating film was immersed in a developing solution at 23° C. for 2 minutes and then cleaned with pure water. Then, post-bake was performed at 200° C. for 80 minutes to form a photosensitive resin layer having a film thickness of 2.0 μm on the glass substrate.

The stripe pattern formed by the method was observed and evaluated using an optical microscope. The evaluation standards are as follows:
⊚: good linearity;
◯: average linearity;
×: poor linearity.

TABLE 2

| | | | Example | | | | | | | | | |
|---|---|---|---|---|---|---|---|---|---|---|---|---|
| Component | | | 1 | 2 | 3 | 4 | 5 | 6 | 7 | 8 | 9 | 10 |
| Alkai-soluble | A-1 | A-1-1 | — | — | — | — | — | — | — | 80 | — | — |
| resin (A) | | A-1-2 | — | — | — | — | — | — | — | — | 50 | — |
| (parts by | | A-1-3 | — | — | — | — | — | — | — | — | — | 10 |
| weight) | A-2 | A-2-1 | 100 | — | — | 100 | — | — | 100 | 20 | — | — |
| | | A-2-2 | — | 100 | — | — | 100 | — | — | — | 50 | — |
| | | A-2-3 | — | — | 100 | — | — | 100 | — | — | — | 90 |
| Compound (B) | B-1 | B-1-1 | 10 | — | — | — | 100 | — | — | — | 100 | — |
| containing an | | B-1-2 | — | 20 | — | — | — | — | — | — | — | — |
| ethylenically | | B-1-3 | — | — | 50 | — | — | — | — | — | — | — |
| unsaturated | | B-1-4 | — | — | — | 70 | — | — | — | — | — | — |
| group (parts | B-2 | B-2-1 | 50 | 80 | — | — | 100 | — | — | 400 | — | — |
| by weight) | | B-2-2 | — | — | 100 | — | — | 200 | — | — | 500 | — |
| | | B-2-3 | — | — | — | 100 | — | — | 300 | — | — | 500 |

| | | | | | | | | | | | |
|---|---|---|---|---|---|---|---|---|---|---|---|
| Photoinitiator | C-1 | 20 | — | — | 50 | — | — | 60 | — | — | 200 |
| (C) | C-2 | — | 30 | — | — | 50 | 50 | — | 100 | — | — |
| (parts by | C-3 | — | — | 40 | — | — | 20 | — | — | 150 | — |
| weight) | C-4 | — | — | — | — | 10 | — | 20 | — | — | — |
| Organic | D-1 | 500 | 500 | — | 2000 | — | 2000 | — | 3000 | 4000 | 5000 |
| solvent (D) | D-2 | — | 500 | 1000 | — | 2000 | 1000 | 3000 | — | 1000 | — |
| (parts by | | | | | | | | | | | |
| weight) | | | | | | | | | | | |
| Compound | E-1 | 1 | — | — | — | — | 10 | — | — | — | — |
| (E) (parts by | E-2 | — | 3 | — | — | — | — | 10 | — | — | — |
| weight) | E-3 | — | — | 5 | — | — | — | 5 | 20 | — | — |
| | E-4 | — | — | — | 10 | — | — | — | — | 30 | — |
| | E-5 | — | — | — | — | 10 | — | — | — | — | 35 |
| | e-1 | — | — | — | — | — | — | — | — | — | — |
| | e-2 | — | — | — | — | — | — | — | — | — | — |
| Pigment (F) | F-1 | — | — | — | 40 | — | — | — | — | — | — |
| (parts by | F-2 | — | — | — | — | 50 | — | — | — | — | — |
| weight) | F-3 | — | — | — | — | — | 100 | 150 | 200 | 300 | 400 |
| Dye (G) | G-1 | — | — | — | — | — | — | 3 | — | — | — |
| (parts by | G-2 | — | — | — | — | — | — | — | 5 | — | — |
| weight) | G-3 | — | — | — | — | — | — | — | — | 20 | — |
| | G-4 | — | — | — | — | — | — | — | — | — | 30 |
| Additive (H) | H-1 | — | 0.1 | — | — | — | — | 5 | — | — | — |
| | H-2 | — | — | — | 5 | — | — | 5 | — | 0.1 | — |

| | | | | | | | | | | |
|---|---|---|---|---|---|---|---|---|---|---|
| Development properties | Δ | ⊚ | ⊚ | ⊚ | ⊚ | ◯ | ◯ | ◯ | ⊚ | Δ |
| High-precision pattern linearity | ◯ | ◯ | ◯ | ◯ | ◯ | ◯ | ◯ | ⊚ | ⊚ | ◯ |

TABLE 3

| | | | Comparative example | | | | |
|---|---|---|---|---|---|---|---|
| Component | | | 1 | 2 | 3 | 4 | 5 |
| Alkai-soluble | A-1 | A-1-1 | — | — | — | — | 50 |
| resin (A) | | A-1-2 | — | — | — | — | — |
| (parts by | | A-1-3 | — | — | — | — | — |
| weight) | A-2 | A-2-1 | 100 | — | — | 100 | — |
| | | A-2-2 | — | 100 | — | — | 50 |
| | | A-2-3 | — | — | 100 | — | — |
| Compound (B) | B-1 | B-1-1 | 50 | — | — | — | — |
| containing an | | B-1-2 | — | — | — | — | — |
| ethylenically | | B-1-3 | — | — | — | — | — |
| unsaturated | | B-1-4 | — | — | — | — | — |
| group (parts | B-2 | B-2-1 | 100 | — | — | 100 | — |
| by weight) | | B-2-2 | — | 100 | — | 50 | 150 |
| | | B-2-3 | — | — | 150 | — | — |

| | | | | | | |
|---|---|---|---|---|---|---|
| Photoinitiator | C-1 | 50 | — | — | — | 50 |
| (C) (parts by | C-2 | — | 50 | — | — | — |
| weight) | C-3 | — | — | 50 | — | — |
| | C-4 | — | — | — | 50 | — |
| Organic | D-1 | 500 | 500 | — | 2000 | — |
| solvent (D) | D-2 | — | 500 | 1000 | — | 2000 |
| (parts by | | | | | | |
| weight) | | | | | | |
| Compound | E-1 | — | — | — | — | — |
| (E) (parts by | E-2 | — | — | — | — | — |
| weight) | E-3 | — | — | — | — | — |
| | E-4 | — | — | — | — | — |
| | E-5 | — | — | — | — | — |
| | e-1 | — | — | 10 | — | 10 |
| | e-2 | — | — | — | 10 | 5 |
| Pigment (F) | F-1 | — | — | — | — | — |
| (parts by | F-2 | — | — | — | — | — |
| weight) | F-3 | — | — | — | — | — |
| Dye (G) | G-1 | — | — | — | — | — |
| (parts by | G-2 | — | — | — | — | — |
| weight) | G-3 | — | — | — | — | — |
| | G-4 | — | — | — | — | — |
| Additive (H) | H-1 | — | 0.1 | — | — | — |
| | H-2 | — | — | — | 5 | — |

| | | | | | |
|---|---|---|---|---|---|
| Development properties | X | X | X | X | X |
| High-precision pattern linearity | X | X | X | X | X |

### Evaluation Results

It can be known from Table 2 and Table 3 that, in comparison to the photosensitive resin composition containing the compound (E) represented by formula (1) (example 1 to example 10), the high-precision pattern linearity and the development properties of the photosensitive resin composition without the compound (E) represented by formula (1) (comparative example 1 to comparative example 5) are worse. It can therefore be known that, when the photosensitive resin composition does not include the compound (E) represented by formula (1), the high-precision pattern linearity and the development properties of the photosensitive resin composition are worse. More specifically, when the usage amount of the compound (E) is within a suitable range, a photosensitive resin composition having better precision pattern linearity can subsequently be manufactured, and development properties can be further improved.

Moreover, when the alkali-soluble resin (A) includes the first alkali-soluble resin (A-1) having an unsaturated group (examples 8 to 10), the high-precision pattern linearity of the photosensitive resin composition is better. It can therefore be known that, when in the photosensitive resin composition, the alkali-soluble resin (A) includes the first alkali-soluble resin (A-1) having an unsaturated group, the high-precision pattern linearity of the photosensitive resin composition is better.

Moreover, when the compound (B) containing an ethylenically unsaturated group is selected from the group consisting of the compound represented by formula (5) and the compound represented by formula (6) (examples 1 to 5 and 9), the development properties of the photosensitive resin composition are better. It can therefore be known that, when in the photosensitive resin composition, the compound (B) containing an ethylenically unsaturated group is selected from the group consisting of the compound represented by formula (5) and the compound represented by formula (6), the development properties of the photosensitive resin composition are better.

Based on the above, the invention provides a photosensitive resin composition that can be applied in a protective film, a spacer, a pixel layer, a color filter, a thin-film transistor, and a liquid crystal display apparatus and can provide good development properties and high-precision pattern linearity.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A photosensitive resin composition, comprising:
an alkai-soluble resin (A);
a compound (B) containing an ethylenically unsaturated group;
a photoinitiator (C);
an organic solvent (D); and
a compound represented by formula (1); 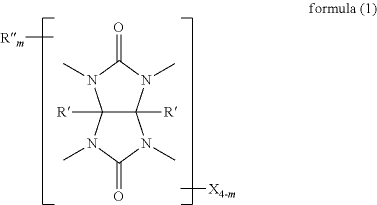
formula (1)
in formula (1), R′ each independently represent a hydrogen atom, a C₁ to C₂₀ substituted or unsubstituted hydrocarbon group or acyl group,
R″ each independently represent a hydrogen atom, a C₁ to C₁₅ substituted or unsubstituted hydrocarbon group, acyl group, or nitro group,
m represents an integer of 0, 1, or 2,
X is a group having a structure represented by formula (2); 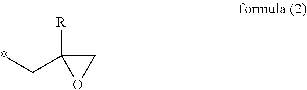
formula (2)
in formula (2), R represents a hydrogen atom or a C₁ to C₄ alkyl group.

2. The photosensitive resin composition of claim 1, wherein the alkali-soluble resin (A) comprises a first alkali-soluble resin (A-1) having an unsaturated group, and the first alkali-soluble resin (A-1) having an unsaturated group is obtained by performing a polymerization reaction on a mixture of an epoxy compound (a1) having at least two epoxy groups and a compound (a2) having at least one carboxylic acid group and at least one ethylenically unsaturated group.

3. photosensitive resin composition of claim 2, wherein the epoxy compound (a1) having at least two epoxy groups is selected from the group consisting a compound represented by formula (3) and a compound represented by formula (4), 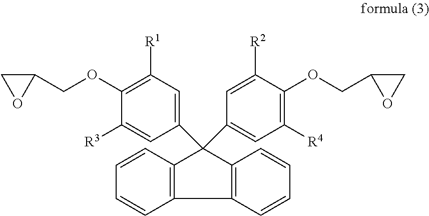
in formula (3), R¹, R², R³, and R⁴ each independently represent a hydrogen atom, a halogen, or a C₁ to C5 alkyl group; 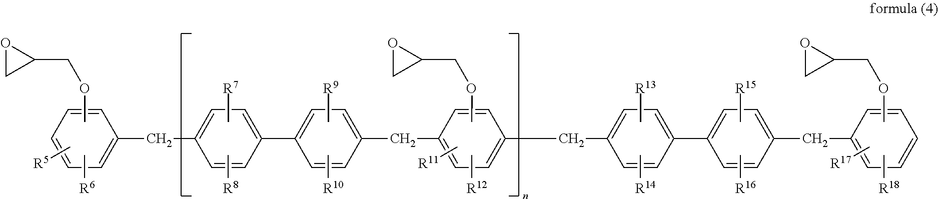
in formula (4), R⁵ to R¹⁸ each independently represent a hydrogen atom, a halogen, a C₁ to C₈ alkyl group, or a C₆ to C15 aryl group,
n represents an integer of 0 to 10.

4. The photosensitive resin composition of claim 2, wherein based on a total usage amount of 100 parts by weight of the alkali-soluble resin (A), a usage amount of the first alkali-soluble resin (A-1) having an unsaturated group is 10 parts by weight to 80 parts by weight.

5. The photosensitive resin composition of claim 1, wherein the compound (B) containing an ethylenically unsaturated group comprises at least one compound (B-1) selected from the group consisting of a compound represented by formula (5) and a compound represented by formula (6), 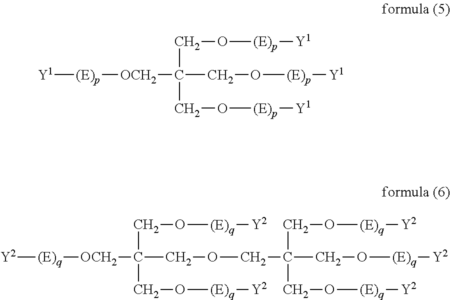
in formula (5) and formula (6), E each independently represent —((CH₂)_{z}CH₂O)— or —((CH₂)_{z}CH(CH₃)O)—, z each independently represent an integer of 1 to 10, Y¹ and Y² each independently represent an acryl group, a methacryl group, a hydrogen atom, or a carboxyl group;
in formula (5), a sum of the acryl group and the methacryl group represented by Y¹ is 3 or 4, p each independently represent an integer of 0 to 10, and a sum of each p is an integer of 1 to 40;
in formula (6), a sum of the acryl group and the methacryl group represented by Y² is 5 or 6, q each independently represent an integer of 0 to 10, and a sum of each q is an integer of 1 to 60.

6. The photosensitive resin composition of claim 5, wherein based on 100 parts by weight of a total usage amount of the alkali-soluble resin (A), a usage amount of the at least one compound (B-1) selected from the group consisting of the compound represented by formula (5) and the compound represented by formula (6) is between 10 parts by weight and 100 parts by weight.

7. The photosensitive resin composition of claim 1, wherein based on a total usage amount of 100 parts by weight of the alkali-soluble resin (A), a usage amount of the compound (B) containing an ethylenically unsaturated group is 60 parts by weight to 600 parts by weight; a usage amount of the photoinitiator (C) is 20 parts by weight to 200 parts by weight; a usage amount of the organic solvent (D) is 500 parts by weight to 5000 parts by weight; and a usage amount of the compound (E) represented by formula (1) is 3 parts by weight to 30 parts by weight.

8. The photosensitive resin composition of claim 1, further comprising a pigment (F).

9. The photosensitive resin composition of claim 8, wherein based on a total usage amount of 100 parts by weight of the alkali-soluble resin (A), a usage amount of the pigment (F) is 40 parts by weight to 400 parts by weight.

10. The photosensitive resin composition of claim 8, further comprising a dye (G).

11. The photosensitive resin composition of claim 10, wherein based on a total usage amount of 100 parts by weight of the alkali-soluble resin (A), a usage amount of the dye (G) is 3 parts by weight to 30 parts by weight.

12. A protective film formed by the photosensitive composition of claim 1.

13. A spacer formed by the photosensitive composition of claim 1.

14. A pixel layer formed by the photosensitive composition of claim 1.

15. A thin-film transistor, containing the protective film of claim 12.

16. A color filter, containing the protective film of claim 12.

17. A color filter, containing the spacer of claim 13.

18. A color filter, containing the pixel layer of claim 14.

19. A liquid crystal display apparatus, containing the thin-film transistor of claim 15.

20. A liquid crystal display apparatus, containing the color filter of any one of claim 16 to claim 18.
